(19) United States
(12) Patent Application Publication
(10) Pub. No.: US 2024/0363607 A1
(43) Pub. Date: Oct. 31, 2024

(54) DISPLAY DEVICE

(71) Applicant: Samsung Display Co., LTD., Yongin-si (KR)

(72) Inventors: Hyun Wook LEE, Yongin-si (KR); Jang Soon PARK, Yongin-si (KR); Sung Geun BAE, Yongin-si (KR); Jun Ho BAE, Yongin-si (KR); Tae Hee LEE, Yongin-si (KR)

(21) Appl. No.: 18/438,099

(22) Filed: Feb. 9, 2024

(30) Foreign Application Priority Data
Apr. 26, 2023 (KR) 10-2023-0055013

(51) Int. Cl. H01L 25/16; H01L 25/075; H01L 27/12; H01L 33/10; H01L 33/62

(52) U.S. Cl. CPC H01L 25/167; H01L 25/0753; H01L 27/124; H01L 33/10; H01L 33/62

(57) ABSTRACT

According to one or more embodiments of the disclosure, a display device comprises a pixel-circuit layer above a base layer and comprising a pixel circuit comprising a transistor comprising an active layer and a trench structure adjacent to the active layer and having reflexibility, and a light-emitting element on the pixel-circuit layer.

### CROSS-REFERENCE TO RELATED APPLICATION

The present application claims priority to, and the benefit of, Korean Patent Application No. 10-2023-0055013 filed on Apr. 26, 2023, in the Korean Intellectual Property Office, the entire disclosure of which is incorporated herein by reference.

### BACKGROUND

### 1. Field

The disclosure relates to a display device.

### 2. Description of the Related Art

In recent years, as interest in information display is increasing, research and development for a display device are continuously being conducted.

### SUMMARY

An aspect of the disclosure provides a display device in which reliability of performance for a pixel circuit may be reconsidered.

According to one or more embodiments of the disclosure, a display device may include a base layer, a pixel-circuit layer above the base layer, and including a pixel circuit including a transistor including an active layer, and a trench structure adjacent to the active layer and having reflexibility, and a light-emitting element above the pixel-circuit layer.

The base layer may be above a plane defined by a first direction, and by a second direction that is different from the first direction, wherein the trench structure includes a reflective surface extending in a direction that is different from a direction in which the plane extends.

The trench structure may include a lower member, an upper member, and an extension member connecting the lower member and the upper member, wherein the upper member is spaced further from the base layer than the lower member, and wherein one surface of the extension member defines the reflective surface.

The pixel-circuit layer may include lower lines including the pixel circuit, a lower auxiliary electrode layer above the base layer, a first interlayer conductive layer above the lower auxiliary electrode layer, and a second interlayer conductive layer above the first interlayer conductive layer and including the trench structure.

The pixel-circuit layer may include lower lines including the pixel circuit, the trench structure, a lower auxiliary electrode layer above the base layer and including an additional lower member of the trench structure between the lower member and the base layer, a first interlayer conductive layer above the lower auxiliary electrode layer, and a second interlayer conductive layer above the first interlayer conductive layer, wherein the first interlayer conductive layer or the second interlayer conductive layer includes the lower member, the extension member, and the upper member.

The display device may further include a first electrode and a second electrode above the pixel-circuit layer, a line-free area in which lower lines, which are of the pixel-circuit layer, and which form the pixel circuit and the trench structure, are not located, and an electrode-free area defined by the first electrode and the second electrode being spaced apart from each other, wherein the electrode-free area is entirely in the line-free area in a plan view.

The electrode-free area may overlap the light-emitting element in plan view.

The transistor may include a driving transistor, wherein the trench structure is between at least a portion of the driving transistor and the electrode-free area in plan view.

The active layer may include a driving active layer of the driving transistor, wherein the trench structure is between the active layer and the light-emitting element in plan view.

The trench structure may include a first trench structure, a second trench structure, and a third trench structure, wherein the pixel circuit includes a first pixel circuit, a second pixel circuit, and a third pixel circuit sequentially arranged in a first direction and below the first trench structure, the second trench structure, and the third trench structure in a second direction crossing the first direction in plan view.

The display device may further include an emission area in which the light-emitting element is located, and including a first emission area, a second emission area, and a third emission area above the first pixel circuit, the second pixel circuit, and the third pixel circuit in the second direction, wherein the first trench structure is aligned with the first pixel circuit and the first emission area in the second direction, wherein the second trench structure is aligned with the second pixel circuit and the second emission area in the second direction, and wherein the third trench structure is aligned with the third pixel circuit and the third emission area in the second direction.

The trench structure may have a shape extending on the first direction.

The pixel-circuit layer may include a line electrically connected to the pixel circuit and integrally formed with the trench structure.

The transistor may include a first transistor including a first gate electrode, a second transistor including a second gate electrode, and a third transistor including a third gate electrode, wherein the line includes a scan line electrically connected to the second gate electrode through a first gate contact portion, and electrically connected to the third gate electrode through a second gate contact portion, and wherein the trench structure is between the first gate contact portion and the second gate contact portion in plan view.

The transistor may include a switching transistor, wherein the line includes a scan line electrically connected to a gate electrode of the switching transistor, and integrally formed with the trench structure.

The line may include a first power line integrally formed with the trench structure for supplying first power, and a second power line for supplying second power.

The trench structure may include a first side trench structure adjacent a first side of the pixel circuit in plan view, and a second side trench structure adjacent a second side of the pixel circuit that is opposite to the first side in plan view.

The transistor may include a switching transistor, wherein the line includes a scan line electrically connected to a gate electrode of the switching transistor and integrally formed with the second side trench structure, a first power line integrally formed with the first side trench structure for supplying first power, and a second power line for supplying second power.

According to one or more embodiments of the disclosure, a display device may include a base layer on a plane defined by a first direction, and by a second direction that is different from the first direction, a pixel-circuit layer above the base layer, and including a pixel circuit including a transistor, and a light-emitting element above the pixel-circuit layer, wherein the pixel circuit includes a reflective structure that is between the transistor and the light-emitting element in a plan view and that includes a reflective surface that is non-parallel to a direction in which the plane extends.

According to one or more embodiments of the disclosure, a display device may include a base layer, a pixel-circuit layer including lower lines above the base layer, and a light-emitting-element layer above the pixel-circuit layer, and including a first electrode, a second electrode, and a light-emitting element between the first electrode and the second electrode, a line-free area in which the lower lines are not located, and an electrode-free area defined by the first electrode and the second electrode being spaced apart from each other, and entirely within the line-free area in a plan view, wherein a portion of the lower lines includes a pixel circuit including a transistor, and at least another portion of the lower lines includes a reflective structure, the reflective structure including a reflective surface between the transistor and the electrode-free area and facing the electrode-free area.

According to one or more embodiments of the disclosure, a display device in which reliability of performance for a pixel circuit may be reconsidered, may be provided.

### BRIEF DESCRIPTION OF THE DRAWINGS

The above and other aspects of the disclosure will become more apparent by describing in further detail embodiments thereof with reference to the accompanying drawings, in which:

FIG. 1 is a schematic perspective view illustrating a light-emitting element according to one or more embodiments;

FIG. 2 is a schematic cross-sectional view illustrating a light-emitting element according to one or more embodiments;

FIG. 3 is a block diagram illustrating a display device according to one or more embodiments;

FIG. 4 is a circuit diagram illustrating a pixel circuit included in a sub-pixel according to one or more embodiments;

FIG. 5 is a schematic cross-sectional view illustrating a stack structure of a display device according to one or more embodiments;

FIGS. 6 and 7 are schematic diagrams illustrating a display device according to one or more embodiments;

FIG. 8 is a schematic cross-sectional view illustrating a display device according to one or more embodiments; and

FIGS. 9 to 18 are schematic diagrams illustrating a structure of a display device including a trench structure according to one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The present disclosure covers all modifications, equivalents, and replacements within the idea and technical scope of the present disclosure. Further, each of the features of the various embodiments of the present disclosure may be combined or combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. In other instances, well-known structures and devices are shown in block diagram form to avoid unnecessarily obscuring various embodiments.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to” may be construed similarly. It will be understood that when an element or layer is referred to as being “between” two elements or layers, it can be the only element or layer between the two elements or layers, or one or more intervening elements or layers may also be present.

For the purposes of this disclosure, expressions, such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expression, such as “at least one of A and B” and “at least one of A or B” may include A, B, or A and B. As used herein, “or” generally means “and/or,” and the term “and/or” includes any and all combinations of one or more of the associated listed items. For example, the expression, such as “A and/or B” may include A, B, or A and B. Similarly, expressions, such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

Some embodiments are described in the accompanying drawings in relation to functional block, unit, and/or module. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

The disclosure relates to a display device. Hereinafter, a display device according to one or more embodiments is described with reference to the accompanying drawings.

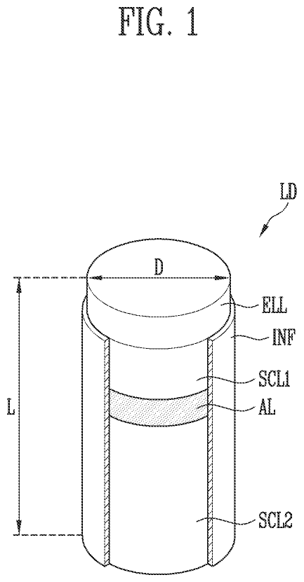

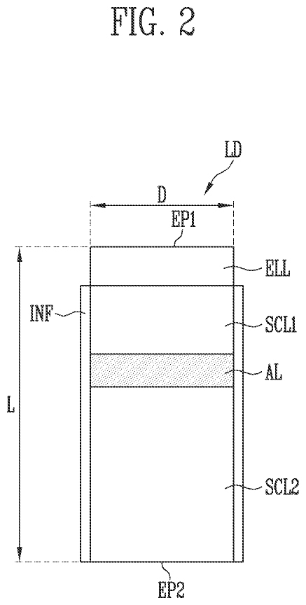

First, a light-emitting element LD according to one or more embodiments is described with reference to FIGS. 1 and 2. FIG. 1 is a schematic perspective view illustrating a light-emitting element according to one or more embodiments. FIG. 2 is a schematic cross-sectional view illustrating a light-emitting element according to one or more embodiments.

The light-emitting element LD is configured to emit light. The light-emitting element LD may include a first semiconductor layer SCL1, a second semiconductor layer SCL2, and an active layer AL located between the first semiconductor layer SCL1 and the second semiconductor layer SCL2. According to one or more embodiments, the first semiconductor layer SCL1, the active layer AL, and the second semiconductor layer SCL2 may be sequentially stacked along a length L direction of the light-emitting element LD. According to one or more embodiments, the light-emitting element LD may further include an electrode layer ELL and an insulating film INF.

The light-emitting element LD may have various shapes. For example, the light-emitting element LD may have a column shape extending in one direction. The column shape may include a rod-like shape or a bar-like shape that is long in the length L direction (for example, an aspect ratio is greater than 1), such as a circular column or a polygonal column, and a cross-sectional shape thereof is not particularly limited.

The light-emitting element LD may have a first end EP1 and a second end EP2. According to one or more embodiments, the first semiconductor layer SCL1 may be adjacent to the first end EP1 of the light-emitting element LD, and the second semiconductor layer SCL2 may be adjacent to the second end EP2. According to one or more embodiments, an electrode layer ELL may be adjacent to the first end EP1.

The light-emitting element LD may be manufactured by etching sequentially stacked semiconductor layers. The light-emitting element LD may have a size of a nano scale to a micro scale. For example, each of a diameter D (or a width) of the light-emitting element LD and a length L of the light-emitting element LD may have a nano scale to a micro scale. However, the disclosure is not necessarily limited thereto.

The first semiconductor layer SCL1 may include a first conductivity type semiconductor. The first semiconductor layer SCL1 may be located on the active layer AL and may include a semiconductor layer of a type that is different from that of the second semiconductor layer SCL2. For example, the first semiconductor layer SCL1 may include a P-type semiconductor layer. For example, the first semiconductor layer SCL1 may include one or more semiconductor materials selected from a group of InAlGaN, GaN, AlGaN, InGaN, AlN, or InN, and may include a P-type semiconductor layer doped with a first conductivity type dopant, such as Ga, B, or Mg. However, the disclosure is not limited to the above-described example. The first semiconductor layer SCL1 may include various materials.

The active layer AL may be located between the first semiconductor layer SCL1 and the second semiconductor layer SCL2. The active layer AL may include a single-quantum well or multi-quantum well structure. A position of the active layer AL is not limited to any specific example, and may be variously changed according to a type of the light-emitting element LD.

A clad layer that is doped with a conductive dopant may be formed on one side and/or another side of the active layer AL. For example, the clad layer may include one or more of AlGaN and/or InAlGaN. However, the disclosure is not necessarily limited to the above-described example.

The second semiconductor layer SCL2 may include a second conductivity type semiconductor. The second semiconductor layer SCL2 may be located on the active layer AL and may include a semiconductor layer of a type that is different from that of the first semiconductor layer SCL1. For example, the second semiconductor layer SCL2 may include an N-type semiconductor layer. For example, the second semiconductor layer SCL2 may include one or more selected from a group of InAlGaN, GaN, AlGaN, InGaN, AlN, and/or InN, and may include an N-type semiconductor layer doped with a second conductivity type dopant, such as Si, Ge, and/or Sn. However, the disclosure is not limited to the above-described example. The second semiconductor layer SCL2 may include various materials.

When a voltage equal to or greater than a threshold voltage is applied to the first end EP1 and the second end EP2 of the light-emitting element LD, an electron-hole pair may recombine with each other in the active layer AL, and the light-emitting element LD may emit light. By controlling light emission of the light-emitting element LD using such a principle, the light-emitting element LD may be used as a light source in various devices.

The insulating film INF may be located on one surface of the light-emitting element LD. The insulating film INF may surround an outer surface of the active layer AL, and may further surround a portion of each of the first semiconductor layer SCL1 and the second semiconductor layer SCL2. The insulating film INF may have a single layer or multiple layer structure.

The insulating film INF may expose the first end EP1 and the second end EP2 of the light-emitting element LD having different polarities. For example, the insulating film INF may expose one end of each of the electrode layer ELL and the second semiconductor layer SCL2 adjacent to the first end EP1 and the second end EP2 of the light-emitting element LD. The insulating film INF may ensure electrical stability of the light-emitting element LD. In addition, the insulating film INF may reduce or minimize a surface defect of the light-emitting element LD to improve lifespan and efficiency. In addition, when a plurality of light-emitting elements LD are located in close to each other, the insulating film INF may reduce or prevent the likelihood of a short defect between the light-emitting elements LD.

According to one or more embodiments, the insulating film INF may include at least one of a group of silicon oxide (SiOx), silicon nitride (SiNx), silicon oxynitride (SiOxNy), aluminum oxide (AlxOy), and/or titanium oxide (TiOx). However, the insulating film INF is not necessarily limited to the example described above in the disclosure.

The electrode layer ELL may be located on the first semiconductor layer SCL1. The electrode layer ELL may be adjacent to the first end EP1. The electrode layer ELL may be electrically connected to the first semiconductor layer SCL1. A portion of the electrode layer ELL may be exposed. For example, the insulating film INF may expose one surface of the electrode layer ELL. The electrode layer ELL may be exposed in an area corresponding to the first end EP1. According to one or more embodiments, a side surface of the electrode layer ELL may be exposed. For example, the insulating film INF may cover side surfaces of each of the first semiconductor layer SCL1, the active layer AL, and the second semiconductor layer SCL2, and may not cover at least a portion of the side surface of the electrode layer ELL. In this case, electrical connection to another configuration of the electrode layer ELL adjacent to the first end EP1 may be easy. According to one or more embodiments, the insulating film INF may expose a portion of the side surface of the first semiconductor layer SCL1 and/or the second semiconductor layer SCL2 as well as the side surface of the electrode layer ELL.

According to one or more embodiments, the electrode layer ELL may be an Ohmic contact electrode. However, the disclosure is not necessarily limited to the above-described example. For example, the electrode layer ELL may be a Schottky contact electrode.

According to one or more embodiments, the electrode layer ELL may include one or more of a group of chromium (Cr), titanium (Ti), aluminum (Al), gold (Au), nickel (Ni), an oxide thereof, and/or an alloy thereof. However, the disclosure is not necessarily limited to the above-described example. According to one or more embodiments, the electrode layer ELL may be substantially transparent. For example, the electrode layer ELL may include indium tin oxide (ITO). Accordingly, the electrode layer ELL may transmit emitted light.

A structure, a shape, or the like of the light-emitting element LD is not limited to the above-described example, and the light-emitting element LD may have various structures and shapes according to one or more embodiments. For example, the light-emitting element LD may further include an additional electrode layer located on one surface of the second semiconductor layer SCL2 and adjacent to the second end EP2.

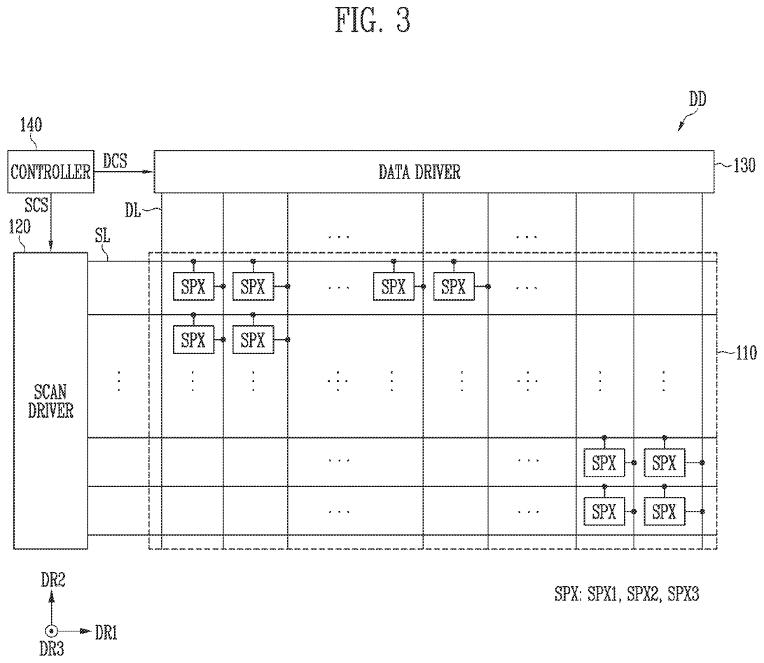

Next, a display device DD according to one or more embodiments is described with reference to FIG. 3. FIG. 3 is a block diagram illustrating a display device according to one or more embodiments.

The display device DD is configured to emit light. The display device DD may be an electronic device using the light-emitting element LD as a light source. According to one or more embodiments, the display device DD may include a pixel unit 110, a scan driver 120, a data driver 130, and a controller 140.

The pixel unit 110 may include a plurality of sub-pixels SPX connected to a scan line SL and a data line DL. According to one or more embodiments, one or more of the sub-pixels SPX may form (or configure) a pixel (or a pixel unit). Each of the sub-pixels SPX may be one of first to third sub-pixels SPX1, SPX2, and SPX3. For example, the sub-pixels SPX may include the first sub-pixel SPX1 for emitting light of a first color (for example, red), the second sub-pixel SPX2 for emitting light of a second color (for example, green), and the third sub-pixel SPX3 for emitting light of a third color (for example, blue). However, the disclosure is not limited to the above-described example.

The scan driver 120 may be located on one side of the pixel unit 110. The scan driver 120 may receive a first control signal SCS from the controller 140. The scan driver 120 may provide a scan signal to the sub-pixel SPX. The scan driver 120 may supply the scan signal to the scan lines SL in response to the first control signal SCS.

The first control signal SCS may be a signal for controlling a driving timing of the scan driver 120. The first control signal SCS may include a scan start signal and a plurality of clock signals for the scan signal. The scan signal may be set to a gate-on level corresponding to a type of a transistor to which a corresponding scan signal is supplied.

The data driver 130 may be located on one side of the pixel unit 110. The data driver 130 may receive a second control signal DCS from the controller 140. The data driver 130 may provide a data signal to the sub-pixel SPX. The data driver 130 may supply the data signal to the data line DL in response to the second control signal DCS. For example, the second control signal DCS may be provided to the sub-pixel SPX through the data line DL. The second control signal DCS may be a signal for controlling a driving timing of the data driver 130.

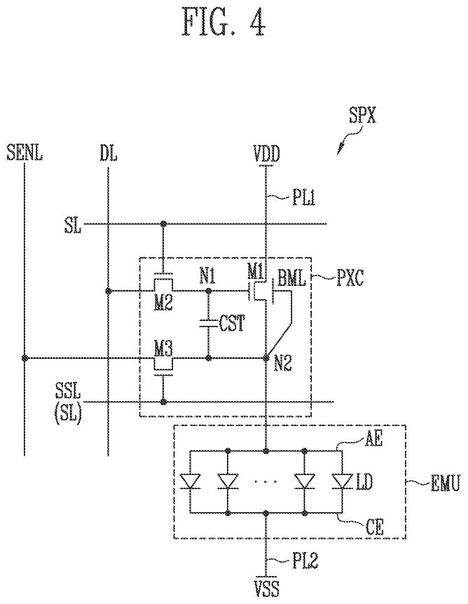

According to one or more embodiments, the display device DD may further include a compensator. The compensator may receive a third control signal, which may be for sensing and for deterioration compensation of the sub-pixels SPX, from the controller 140. The compensator may receive a sensing value (e.g., current or voltage information) extracted from the sub-pixel SPX through a sensing line SENL (refer to FIG. 4). The compensator may generate a compensation value for compensating deterioration of the sub-pixel SPX based on the sensing value.

A portion of the scan line SL may extend in a first direction DR1, and may be electrically connected to the sub-pixel SPX of a corresponding pixel row through another portion of the scan line SL extending in a second direction DR2. Accordingly, the scan line SL may supply the scan signal to the corresponding sub-pixel SPX.

The data line DL may extend along a pixel column (for example, in the second direction DR2) and may be electrically connected to the sub-pixel SPX. The data line DL may supply the data signal to the connected sub-pixel SPX.

Here, a pixel row direction may be a horizontal direction and may mean the first direction DR1. The pixel column direction may be a vertical direction and may mean the second direction DR2.

In FIG. 3, the scan driver 120, the data driver 130, and the controller 140 are shown separately, but at least a portion of the scan driver 120, the data driver 130, and the controller 140 may be integrated into one module or integrated circuit (IC) chip.

FIG. 4 is a diagram illustrating a pixel circuit included in a sub-pixel according to one or more embodiments. Referring to FIG. 4, the sub-pixel SPX may include the pixel circuit PXC. The pixel circuit PXC may be configured to drive a light-emitting unit EMU (or the light-emitting elements LD). Each of the sub-pixels SPX for forming one pixel unit may include the pixel circuit PXC.

The pixel circuit PXC may be electrically connected to the scan line SL, the data line DL, a first power line PL1, and a second power line PL2.

The sub-pixel SPX may include the light-emitting unit EMU (or the light-emitting elements LD) configured to emit light corresponding to the data signal provided from the data line DL.

The pixel circuit PXC may be located between the first power line PL1 and the light-emitting unit EMU. The pixel circuit PXC may be electrically connected to the scan line SL to which a first scan signal is supplied, and to the data line DL to which the data signal is supplied. The pixel circuit PXC may be electrically connected to a scan control line SSL to which a second scan signal is supplied, and may be electrically connected to reference power (or initialization power) or the sensing line SENL connected to a sensing circuit. According to one or more embodiments, the second scan signal may be a same as, or different from, the first scan signal. When the second scan signal is a same as the first scan signal, the scan control line SSL may be integrated with the scan line SL. The sensing line SENL may be an initialization power line.

The pixel circuit PXC may include one or more circuit elements. For example, the pixel circuit PXC may include a first transistor M1, a second transistor M2, a third transistor M3, and a storage capacitor CST.

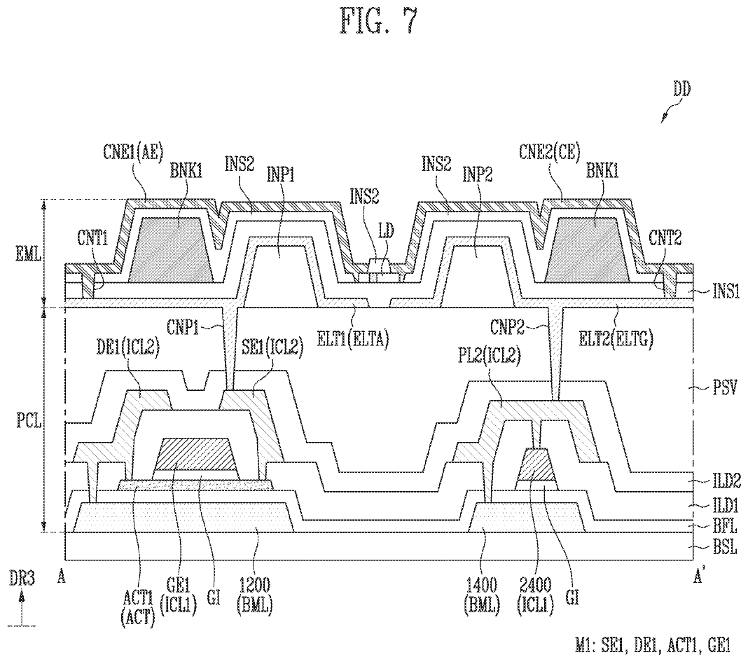

The first transistor M1 may be electrically connected between the first power line PL1 and a second node N2. The second node N2 may be a node to which the pixel circuit PXC and the light-emitting unit EMU are connected. For example, the second node N2 may be a node to which a first source electrode SE1 (refer to FIG. 7) of the first transistor M1 and an anode connection electrode AE of the light-emitting unit EMU are connected. A first gate electrode GE1 (refer to FIG. 7) of the first transistor M1 may be electrically connected to a first node N1. The first transistor M1 may control a driving current supplied to the light-emitting unit EMU in response to a voltage of the first node N1. The first transistor M1 may be a driving transistor.

According to one or more embodiments, a portion of a lower auxiliary electrode layer BML (for example, a first lower auxiliary electrode layer 1200 shown in FIG. 7) may be located under the first transistor M1. In this case, there may be applied a back-bias technology (or sync technology) for moving a threshold voltage of the first transistor M1 in a negative direction or in a positive direction by applying a back-biasing voltage to the first lower auxiliary electrode layer 1200 when driving the sub-pixel SPX.

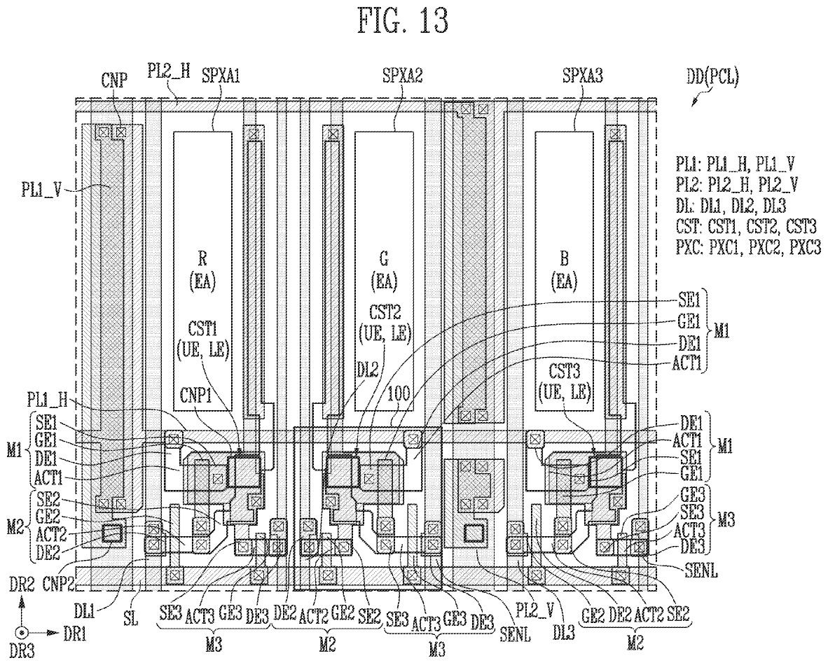

The second transistor M2 may be electrically connected between the data line DL and the first node N1. In addition, a second gate electrode GE2 (refer to FIG. 13) of the second transistor M2 may be electrically connected to the scan line SL. The second transistor M2 may be turned on when a first scan signal of a gate-on voltage (for example, a high level voltage) is supplied from the scan line SL, to thereby electrically connect the data line DL and the first node N1.

For each frame period, a data signal of a corresponding frame is supplied to the data line DL, and the data signal is transferred to the first node N1 through the second transistor M2 during a period in which the first scan signal of the gate-on voltage is supplied. The second transistor M2 may be a switching transistor for transferring each data signal to an inside of the sub-pixel SPX.

One electrode of the storage capacitor CST may be electrically connected to the first node N1, and another electrode thereof may be electrically connected to the second node N2. The storage capacitor CST is charged with a voltage corresponding to the data signal supplied to the first node N1 during each frame period.

The third transistor M3 may be electrically connected between the second node N2 and the sensing line SENL. A third gate electrode GE3 (refer to FIG. 13) of the third transistor M3 may be connected to the scan control line SSL (or to the scan line SL). The third transistor M3 may be turned on when a second scan signal (or a first scan signal) of a gate-on voltage (for example, a high level voltage) is supplied from the scan control line SSL, to thereby transfer a reference voltage (or an initialization voltage) supplied to the sensing line SENL to the second node N2, or to thereby transfer a voltage of the second node N2 to the sensing line SENL. The voltage of the second node N2 transferred to the sensing circuit through the sensing line SENL may be provided to an external circuit (for example, the controller 140) to be used for compensating for a characteristic deviation of the sub-pixels SPX.

In FIG. 4, all of the transistors included in the pixel circuit PXC are N-type transistors, but the disclosure is not limited thereto. For example, at least one of the first, second, and/or third transistors M1, M2, and/or M3 may be changed to a P-type transistor. In addition, a structure and a driving method of the sub-pixel SPX may be variously changed according to one or more embodiments.

The light-emitting unit EMU may include the anode connection electrode AE, a cathode connection electrode CE, and one or more light-emitting elements LD electrically connected between the first power line PL1 and the second power line PL2. For example, the light-emitting unit EMU may include the anode connection electrode AE connected to the first power line PL1 through the first transistor M1, the cathode connection electrode CE connected to the second power line PL2, and one or more light-emitting elements LD connected between the anode connection electrode AE and the cathode connection electrode CE. According to one or more embodiments, the light-emitting unit EMU may include a plurality of light-emitting elements LD connected in parallel between the anode connection electrode AE and the cathode connection electrode CE.

Power of the first power line PL1 and power of the second power line PL2 may have different potentials. For example, the first power line PL1 may be configured to be electrically connected to high-potential pixel power VDD to receive high-potential power, and the second power line PL2 may be configured to be electrically connected to low-potential pixel power VSS to receive low-potential power. A potential difference between the power of the first power line PL1 and the power of the second power line PL2 (for example, a potential difference between the high-potential pixel power VDD and the low-potential pixel power VSS) may be set to a threshold voltage or more of the light-emitting elements LD.

The first power line PL1 may be electrically connected to the first transistor M1. The second power line PL2 may be electrically connected to the cathode connection electrode CE.

Each light-emitting element LD may be connected in a forward direction between the first power line PL1 and the second power line PL2 to form each effective light source. These effective light sources may be gathered to form the light-emitting unit EMU of the sub-pixel SPX.

The light-emitting elements LD may emit light with a luminance corresponding to the driving current supplied through the pixel circuit PXC. During each frame period, the pixel circuit PXC may supply the driving current corresponding to the data signal to the light-emitting unit EMU. The driving current supplied to the light-emitting unit EMU may be divided and flowed to the light-emitting elements LD. Accordingly, while each light-emitting element LD emits light with a luminance corresponding to the current flowing therethrough, the light-emitting unit EMU may emit light with the luminance corresponding to the driving current.

Meanwhile, in FIG. 4, one or more embodiments in which the sub-pixel SPX includes a light-emitting unit EMU of a parallel structure is disclosed, but the disclosure is not limited thereto. For example, the sub-pixel SPX may include a light-emitting unit EMU of a series structure or of a series/parallel structure. The pixel circuit PXC for the sub-pixel SPX according to one or more embodiments is not limited to the above-described example. According to one or more embodiments, the pixel circuit PXC may include seven transistors and one storage capacitor.

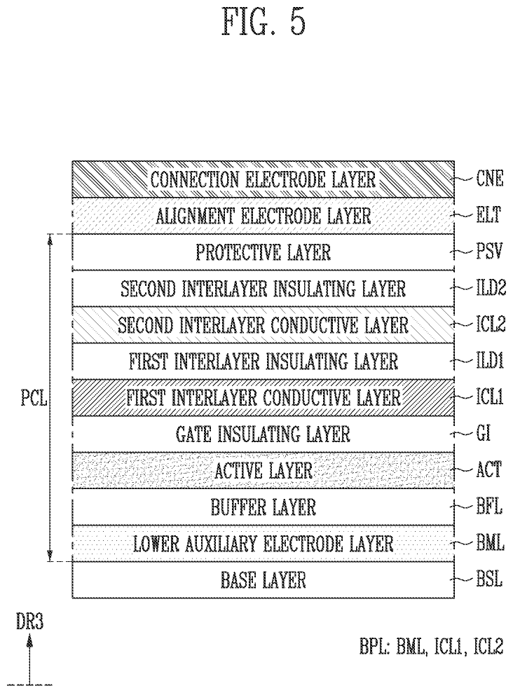

Hereinafter, a display device DD according to one or more embodiments is described with reference to FIGS. 5 to 18.

The display device DD according to one or more embodiments may include a trench structure TS configured to guide a light path. The trench structure TS may be a reflective structure RS.

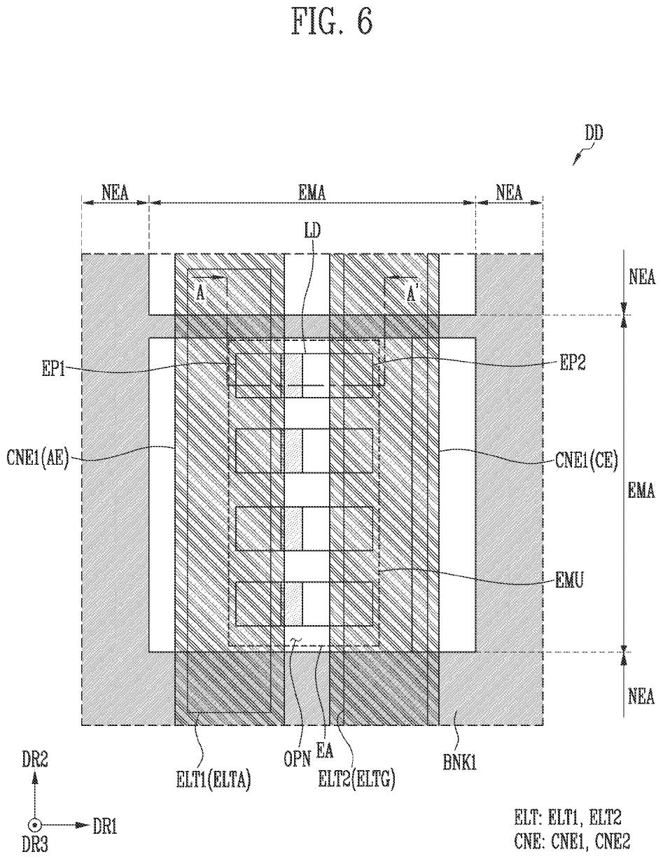

First, referring to FIG. 5, a stack structure defined in the display device DD is described. FIG. 5 is a schematic cross-sectional view illustrating a stack structure of a display device according to one or more embodiments. In the drawings after FIG. 6, layers that are the same as the layers described above with reference to FIG. 5 (for example, patterning within a same process) may be expressed by a same hatching.

Referring to FIG. 5, the stack structure included in the display device DD according to one or more embodiments may have a shape in which at least a portion is patterned in a structure in which the base layer BSL, the lower auxiliary electrode layer BML, a buffer layer BFL, an active layer ACT, a gate-insulating layer G1, a first interlayer conductive layer ICL1, a first interlayer insulating layer ILD1, a second interlayer conductive layer ICL2, a second interlayer insulating layer ILD2, a protective layer PSV, an alignment electrode layer ELT, and a connection electrode layer CNE are sequentially stacked.

According to one or more embodiments, the lower auxiliary electrode layer BML, the buffer layer BFL, the active layer ACT, the gate-insulating layer G1, the first interlayer conductive layer ICL1, the first interlayer insulating layer ILD1, the second interlayer conductive layer ICL2, the second interlayer insulating layer ILD2, and the protective layer PSV may form a pixel-circuit layer PCL including the pixel circuits PXC. According to one or more embodiments, the lower auxiliary electrode layer BML, the first interlayer conductive layer ICL1, and the second interlayer conductive layer ICL2 may form lower lines BPL. Here, the lower lines BPL may be lines forming the pixel-circuit layer PCL, and may include lines (for example, wires or electrodes) that are formed below the alignment electrode layer ELT.

The base layer BSL may form (or configure) a base surface of the display device DD. The base layer BSL may include a rigid or flexible substrate or film. For example, the base layer BSL may be a glass substrate. A material or a configuration material of the base layer BSL is not limited to any specific example, and the base layer BSL may include various materials.

The buffer layer BFL may reduce or prevent diffusion or moisture permeation of an impurity into the active layer ACT. According to one or more embodiments, the buffer layer BFL may include one or more of a group of silicon nitride (SiNx), silicon oxide (SiOx), silicon oxynitride (SiOxNy), and/or aluminum oxide (AlxOy). However, the disclosure is not necessarily limited to the above-described example.

The active layer ACT may include a semiconductor. For example, the active layer ACT may include one or more of a group of polysilicon, low temperature polycrystalline silicon (LTPS), amorphous silicon, and/or an oxide semiconductor. According to one or more embodiments, the active layer ACT may form a channel of the first transistor M1, the second transistor M2, and the third transistor M3. An impurity may be doped in a portion of the active layer ACT contacting source/drain electrodes (for example, a first source electrode SE1 and a first drain electrode DE1 of FIG. 7).

The lower auxiliary electrode layer BML, the first interlayer conductive layer ICL1, the second interlayer conductive layer ICL2, the alignment electrode layer ELT, and the connection electrode layer CNE may include a conductive material.

According to one or more embodiments, each of the lower auxiliary electrode layer BML, the first interlayer conductive layer ICL1, and the second interlayer conductive layer ICL2 may include one or more conductive layers. According to one or more embodiments, each of the lower auxiliary electrode layer BML, the first interlayer conductive layer ICL1, and the second interlayer conductive layer ICL2 may include one or more of a group of gold (Au), silver (Ag), aluminum (Al), molybdenum (Mo), chromium (Cr), titanium (Ti), nickel (Ni), neodymium (Nd), copper (Cu), and/or platinum (Pt). According to one or more embodiments, the second interlayer conductive layer ICL2 may have a multilayer structure in which titanium (Ti), copper (Cu), and indium tin oxide (ITO) are sequentially stacked. However, the disclosure is not necessarily limited to the above-described example.

The gate-insulating layer G1, the first interlayer insulating layer ILD1, the second interlayer insulating layer ILD2, and the protective layer PSV may be located between respective layers to electrically separate the active layer ACT, the first interlayer conductive layer ICL1, the second interlayer insulating layer ICL2, and the alignment electrode layer ELT from each other. According to one or more embodiments, the above-described conductive layers may be electrically connected to each other through contact member(s) CNP formed in one or more of the gate-insulating layer G1, the first interlayer insulating layer ILD1, the second interlayer insulating layer ILD2, and/or the protective layer PSV.

According to one or more embodiments, the gate-insulating layer G1, the first interlayer insulating layer ILD1, and the second interlayer insulating layer ILD2 may include an inorganic material. For example, the inorganic material may include one or more of a group of silicon nitride (SiNx), silicon oxide (SiOx), silicon oxynitride (SiOxNy), and/or aluminum oxide (AlxOy). According to one or more embodiments, the protective layer PSV may include an organic material. For example, the organic material may include one or more of a group of acrylic resin, epoxy resin, phenol resin, polyamide resin, polyimide resin, polyester resin, polyphenylenesulfide resin, and/or benzocyclobutene (BCB). However, the disclosure is not necessarily limited to the above-described example.

According to one or more embodiments, the alignment electrode layer ELT may include a conductive material. For example, the alignment electrode layer ELT may include one or more of a group of molybdenum (Mo), magnesium (Mg), silver (Ag), platinum (Pt), palladium (Pd), gold (Au), nickel (Ni), neodymium (Nd), iridium (Ir), chromium (Cr), titanium (Ti), copper (Cu), and/or aluminum (Al). However, the disclosure is not necessarily limited to the above-described example.

According to one or more embodiments, the connection electrode layer CNE may include a conductive material. The connection electrode layer CNE may be electrically connected to the light-emitting element LD. According to one or more embodiments, the connection electrode layer CNE may include a transparent conductive material. For example, the connection electrode layer CNE may include one or more of a group of indium tin oxide (ITO), indium zinc oxide (IZO), and/or indium tin zinc oxide (ITZO). However, the disclosure is not necessarily limited to the above-described example. A first insulating layer INS1 (refer to FIG. 7) may be located between the alignment electrode layer ELT and the connection electrode layer CNE.

Next, a schematic planar and cross-sectional structure of a display device DD according to one or more embodiments is described with reference to FIGS. 6 to 8.

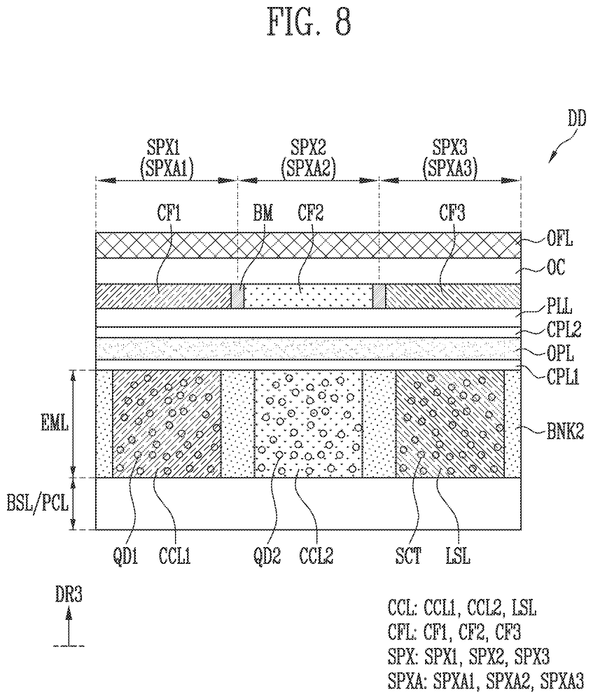

FIGS. 6 and 7 are schematic diagrams illustrating a display device according to one or more embodiments. FIG. 6 is a schematic plan view illustrating a display device DD according to one or more embodiments. FIG. 7 is a schematic cross-sectional view along the line A˜A′ of FIG. 6. FIG. 8 is a schematic cross-sectional view illustrating a display device according to one or more embodiments.

The display device DD may include an emission area EMA and a non-emission area NEA. The display device DD may include a first bank BNK1, the alignment electrode layer ELT, the light-emitting element LD, and the connection electrode layer CNE.

The emission area EMA may overlap an opening OPN defined by the first bank BNK1 in a plan view. The light-emitting elements LD may be located in the emission area EMA. The light-emitting elements LD may not be located in the non-emission area NEA.

The first bank BNK1 may form (or provide, or define) the opening OPN. For example, the first bank BNK1 may have a shape protruding in a thickness direction (for example, a third direction DR3) of the base layer BSL, and may surround one or more areas. According to one or more embodiments, an ink including the light-emitting element LD may be supplied to the opening OPN defined by the first bank BNK1, and the light-emitting element LD may be located in the opening OPN.

According to one or more embodiments, the first bank BNK1 may include an organic material, such as acrylic resin, epoxy resin, phenol resin, polyamide resin, polyimide resin, polyimide resin, polyester resin, polyphenylenesulfide resin, or benzocyclobutene (BCB). However, the disclosure is not limited to the above-described example.

The alignment electrode layer ELT may include electrodes for aligning the light-emitting elements LD. According to one or more embodiments, the alignment electrode layer ELT may include a first electrode ELT1 and a second electrode ELT2. According to one or more embodiments, the first electrode ELT1 may be a first alignment electrode ELTA, and the second electrode ELT2 may be a second alignment electrode ELTG.

The light-emitting element LD may be located (or aligned) on the alignment electrode layer ELT. According to one or more embodiments, the light-emitting element LD may be aligned between the first electrode ELT1 and the second electrode ELT2 in a plan view. The light-emitting elements LD may form (or configure) the light-emitting unit EMU.

According to one or more embodiments, the first electrode ELT1 and the second electrode ELT2 may be spaced apart from each other on the first direction DR1 in the emission area EMA.

According to one or more embodiments, the first electrode ELT1, which is the first alignment electrode ELTA, may be an electrode to which an AC signal is supplied to align the light-emitting elements LD. The first electrode ELT1 may be an electrode to which an anode signal is supplied so that the light-emitting elements LD emit light. The second electrode ELT2, which is the second alignment electrode ELTG, may be an electrode to which a ground signal is supplied to align the light-emitting elements LD. The second electrode ELT2 may be an electrode to which a cathode signal is supplied so that the light-emitting elements LD emit light.

The first electrode ELT1 (or the first alignment electrode ELTA) and the second electrode ELT2 (or the second alignment electrode ELTG) may be supplied (or provided) with a first alignment signal and a second alignment signal, respectively, in a process step in which the light-emitting elements LD are aligned. For example, the ink including the light-emitting element LD may be supplied (or provided) to the opening OPN, the first alignment signal may be supplied to the first electrode ELT1, and the second alignment signal may be supplied to the second electrode ELT2. At this time, the first alignment signal and the second alignment signal may have different waveforms, potentials, and/or phases. For example, the first alignment signal may be an AC signal, and the second alignment signal may be a ground signal. However, the disclosure is not necessarily limited to the above-described example. An electric field may be formed between (or on) the first electrode ELT1 and the second electrode ELT2, and the light-emitting elements LD may be aligned between the first electrode ELT1 and the second electrode ELT2 based on the electric field. For example, the light-emitting elements LD may be moved (or rotated) by force (for example, dielectrophoresis (DEP) force) according to the electric field, and may be aligned (or located) on the first alignment electrode ELTA and the second alignment electrode ELTG.

The light-emitting element LD may emit light based on a provided electrical signal. For example, the light-emitting element LD may provide the light based on a first electrical signal (for example, the anode signal) provided from a first connection electrode CNE1 and based on a second electrical signal (for example, the cathode signal) provided from a second connection electrode CNE2.

The first end EP1 of the light-emitting element LD may be located adjacent to the first electrode ELT1, and the second end EP2 of the light-emitting element LD may be located adjacent to the second electrode ELT2.

The light-emitting element LD may be located within the opening OPN. The light-emitting element LD may form the emission area EA. The emission area EA may be defined as an area where the light-emitting element LD is located. The emission area EA may include an area where the light-emitting element LD is located.

The connection electrode layer CNE may be located on the first ends EP1 and the second ends EP2 of the light-emitting elements LD. The first connection electrode CNE1 may be located on the first ends EP1 of the light-emitting elements LD to be electrically connected to the first ends EP1 of the light-emitting elements LD. The second connection electrode CNE2 may be located on the second ends EP2 of the light-emitting elements LD to be electrically connected to the second ends EP2 of the light-emitting elements LD.

According to one or more embodiments, the connection electrode layer CNE may include the first connection electrode CNE1 and the second connection electrode CNE2. The first connection electrode CNE1 may be the anode connection electrode AE, and the second connection electrode CNE2 may be the cathode connection electrode CE.

FIG. 7 schematically shows a cross-sectional structure of the display device DD based on the pixel-circuit layer PCL in which the pixel circuit PXC is formed, and based on a light-emitting-element layer EML in which the light-emitting elements LD are located.

Referring to FIG. 7, the display device DD may include the pixel-circuit layer PCL and the light-emitting-element layer EML. FIG. 7 is shown based on the first transistor M1 among the pixel circuits PXC for convenience of description.

The base layer BSL may provide an area in which the pixel-circuit layer PCL and the light-emitting-element layer EML are located.

The pixel-circuit layer PCL may be located on the base layer BSL. The pixel-circuit layer PCL may include the layers described above with reference to FIG. 5. For example, the pixel-circuit layer PCL may include the first lower auxiliary electrode layer 1200, a second lower auxiliary electrode layer 1400, the first transistor M1, and the second power line PL2.

The first lower auxiliary electrode layer 1200 and the second lower auxiliary electrode layer 1400 may be formed by the lower auxiliary electrode layer BML. The first lower auxiliary electrode layer 1200 may be electrically connected to the first drain electrode DE1 of the first transistor M1, and may overlap a first active layer ACT1 of the first transistor M1 in a plan view. The second lower auxiliary electrode layer 1400 may be electrically connected to the second power line PL2.

The buffer layer BFL may be located on the base layer BSL. The buffer layer BFL may cover the lower auxiliary electrode layer BML.

The first transistor M1 may be a thin film transistor. The first transistor M1 may be electrically connected to the light-emitting element LD. According to one or more embodiments, the first transistor M1 may include the first active layer ACT1, the first drain electrode DE1, the first source electrode SE1, and the first gate electrode GE1.

The first active layer ACT1 may be formed by the active layer ACT, and may include a first contact area contacting the first drain electrode DE1, and may include a second contact area contacting the first source electrode SE1. According to one or more embodiments, the first active layer ACT1 may be a driving active layer.

The first gate electrode GE1 may be located on the gate-insulating layer G1. A position of the first gate electrode GE1 may correspond to a position of a channel area of the first active layer ACT1.

The gate-insulating layer G1 may be located on the buffer layer BFL. The gate-insulating layer G1 may cover the first active layer ACT1.

The first interlayer insulating layer ILD1 may be located on the gate-insulating layer G1. The first interlayer insulating layer ILD1 may cover the first gate electrode GE1 and a conductive layer 2400. The conductive layer 2400 may be formed by the first interlayer conductive layer ICL1 and may be electrically connected to the second power line PL2.

The first drain electrode DE1 and the first source electrode SE1 may be located on the first interlayer insulating layer ILD1. The first drain electrode DE1 may be electrically connected to the first power line PL1. The first source electrode SE1 may be electrically connected to the first electrode ELT1 through a first contact member CNP1 passing through the second interlayer insulating layer ILD2 and the protective layer PSV.

The second power line PL2 may be located on the first interlayer insulating layer ILD1. The second power line PL2 may be electrically connected to the second lower auxiliary electrode layer 1400, and may be electrically connected to the second electrode ELT2 through a second contact member CNP2 passing through the second interlayer insulating layer ILD2 and the protective layer PSV.

The second interlayer insulating layer ILD2 may be located on the first interlayer insulating layer ILD1. The second interlayer insulating layer ILD2 may cover the first drain electrode DE1, the first source electrode SE1, and the second power line PL2.

The protective layer PSV may be located on the second interlayer insulating layer ILD2. According to one or more embodiments, the protective layer PSV may be a via layer.

The light-emitting-element layer EML may be located on the pixel-circuit layer PCL. The light-emitting-element layer EML may include first and second insulating patterns INP1 and INP2, the alignment electrode layer ELT, the first insulating layer INS1, the first bank BNK1, the light-emitting element LD, a second insulating layer INS2, and the connection electrode layer CNE.

The first and second insulating patterns INP1 and INP2 may be located on the protective layer PSV. The first and second insulating patterns INP1 and INP2 may have various shapes according to one or more embodiments. In one or more embodiments, the first and second insulating patterns INP1 and INP2 may protrude in the thickness direction (for example, the third direction DR3) of the base layer BSL.

The first and second insulating patterns INP1 and INP2 may form a step difference (e.g., a predetermined step difference) so that the light-emitting elements LD may be readily aligned in the emission area EMA. According to one or more embodiments, the first and second insulating patterns INP1 and INP2 may be a partition wall. According to one or more embodiments, the first and second insulating patterns INP1 and INP2 may include at least one organic material and/or inorganic material. However, the disclosure is not necessarily limited to specific example.

The alignment electrode layer ELT may be located on the protective layer PSV and/or the first and second insulating patterns INP1 and INP2. The first electrode ELT1 may receive the first alignment signal and/or first power through the first contact member CNP1. The second electrode ELT2 may receive the second alignment signal and/or second power through the second contact member CNP2.

The first insulating layer INS1 may be located on the alignment electrode layer ELT. For example, the first insulating layer INS1 may cover the first electrode ELT1 and the second electrode ELT2.

The first bank BNK1 may be located on the first insulating layer INS1. As described above, the first bank BNK1 may form a space in which the ink including the light-emitting element LD may be accommodated.

The light-emitting element LD may be located on the first insulating layer INS1 in an area surrounded by the first bank BNK1. According to one or more embodiments, the light-emitting element LD may emit light based on the electrical signals (for example, the anode signal and the cathode signal) provided from the first connection electrode CNE1 and the second connection electrode CNE2.

The second insulating layer INS2 may be located on the light-emitting element LD. The second insulating layer INS2 may cover the active layer AL of the light-emitting element LD. The second insulating layer INS2 may expose at least a portion of the light-emitting element LD. For example, the second insulating layer INS2 may not cover the first end EP1 or the second end EP2 of the light-emitting element LD, and thus the first end EP1 and the second end EP2 of the light-emitting element LD may be exposed and may be electrically connected to the first connection electrode CNE1 and the second connection electrode CNE2, respectively. According to one or more embodiments, another portion of the second insulating layer INS2 may be located on the first bank BNK1 and the first insulating layer INS1.

When the second insulating layer INS2 is formed on the light-emitting elements LD after the alignment of the light-emitting elements LD is completed, the likelihood of the light-emitting elements LD being separated from an aligned position may be reduced or prevented.

The second insulating layer INS2 may have a structure of a sing layer or multiple layers. The second insulating layer INS2 may include one or more of a group of silicon oxide (SiOx), silicon nitride (SiNx), silicon oxynitride (SiOxNy), aluminum nitride (AlNx), aluminum oxide (AlxOy), zirconium oxide (ZrOx), hafnium oxide (HfOx), and/or titanium oxide (TiOx). However, the disclosure is not limited to the above-described example.

The first connection electrode CNE1 and the second connection electrode CNE2 may be respectively located on the first insulation layer INS1 and the second insulation layer INS2. The first connection electrode CNE1 may be electrically connected to the first end EP1 of the light-emitting element LD. The second connection electrode CNE2 may be electrically connected to the second end EP2 of the light-emitting element LD.

The first connection electrode CNE1 may be electrically connected to the first electrode ELT1 through a first contact portion CNT1 passing through the first insulating layer INS1, and the second connection electrode CNE2 may be electrically connected to the second electrode ELT2 through a second contact portion CNT2 passing through the first insulating layer INS1. According to one or more embodiments, the first connection electrode CNE1 may be directly electrically connected to a line of the pixel-circuit layer PCL through the first contact portion CNT1. The second connection electrode CNE2 may be directly electrically connected to a line of the pixel-circuit layer PCL through the second contact portion CNT2.

According to one or more embodiments, the first connection electrode CNE1 and the second connection electrode CNE2 may be patterned at a same time in a same process. However, the disclosure is not necessarily limited to the above-described example. After any one of the first connection electrode CNE1 and the second connection electrode CNE2 is patterned, the other electrode may be patterned.

FIG. 8 schematically shows a cross-sectional structure of the display device DD based on configurations located on the light-emitting-element layer EML.

Referring to FIG. 8, sub-pixel areas SPXA respectively corresponding to the sub-pixels SPX may be formed in the display area DA. The sub-pixel areas SPXA may include a first sub-pixel area SPXA1 corresponding to the first sub-pixel SPX1, a second sub-pixel area SPXA2 corresponding to the second sub-pixel SPX2, and a third sub-pixel area SPXA3 corresponding to the third sub-pixel SPX3. The first sub-pixel area SPXA1, the second sub-pixel area SPXA2, and the third sub-pixel area SPXA3 may be arranged on the first direction DR1.

A second bank BNK2 may be located between or at a boundary between the first to third sub-pixel areas SPXA1, SPXA2, and SPXA3, and may define a space (or an area) overlapping each of the first to third sub-pixel areas SPXA1, SPXA2, and SPXA3. The space defined by the second bank BNK2 may be an area where a color conversion layer CCL may be provided.

The second bank BNK2 may be located to surround one area of the light-emitting-element layer EML. The second bank BNK2 may protrude in the thickness direction (for example, the third direction DR3) of the base layer BSL, and thus the second bank BNK2 may define one area. A space where the color conversion layer CCL is provided may be formed in the opening OPN.

The second bank BNK2 may include an organic material, such as acrylic resin, epoxy resin, phenol resin, polyamide resin, polyimide resin, polyester resin, polyphenylenesulfide resin, or benzocyclobutene. However, the disclosure is not necessarily limited thereto.

The color conversion layer CCL may be located on the light-emitting elements LD in the space surrounded by the second bank BNK2. The color conversion layer CCL may include a first color conversion layer CCL1 located in the first sub-pixel SPX1, a second color conversion layer CCL2 located in the second sub-pixel SPX2, and a scattering layer LSL located in the third sub-pixel SPX3.

The color conversion layer CCL may be located on the light-emitting element LD. The color conversion layer CCL may be configured to change a wavelength of light. According to one or more embodiments, the first to third sub-pixels SPX1, SPX2, and SPX3 may include light-emitting elements LD for emitting light of a same color as each other. For example, the first to third sub-pixels SPX1, SPX2, and SPX3 may include light-emitting elements LD for emitting light of the third color (or blue). As the color conversion layer CCL including color conversion particles is located on each of the first to third sub-pixels SPX1, SPX2, and SPX3, a full color image may be displayed.

The first color conversion layer CCL1 may include first color conversion particles that convert the light of the third color emitted from the light-emitting element LD into the light of the first color. For example, the first color conversion layer CCL1 may include a plurality of first quantum dots QD1 dispersed in one matrix material, such as a base resin.

According to one or more embodiments, when the light-emitting element LD is a blue light-emitting element for emitting blue light and when the first sub-pixel SPX1 is a red pixel, the first color conversion layer CCL1 may include a first quantum dot QD1 for converting the blue light emitted from the blue light-emitting element into red light. The first quantum dot QD1 may absorb the blue light and may emit the red light by shifting a wavelength according to an energy transition. Meanwhile, when the first sub-pixel SPX1 is a pixel of another color, the first color conversion layer CCL1 may include a first quantum dot QD1 corresponding to the color of the first sub-pixel SPX1.

The second color conversion layer CCL2 may include second color conversion particles that convert the light of the third color emitted from the light-emitting element LD into the light of the second color. For example, the second color conversion layer CCL2 may include a plurality of second quantum dots QD2 dispersed in one matrix material, such as a base resin.

According to one or more embodiments, when the light-emitting element LD is the blue light-emitting element for emitting the blue light and when the second sub-pixel SPX2 is a green pixel, the second color conversion layer CCL2 may include a second quantum dot QD2 for converting the blue light emitted from the blue light-emitting element into green light. The second quantum dot QD2 may absorb the blue light and may emit the green light by shifting a wavelength according to an energy transition. Meanwhile, when the second sub-pixel SPX2 is a pixel of another color, the second color conversion layer CCL2 may include a second quantum dot QD2 corresponding to the color of the second sub-pixel SPX2.

According to one or more embodiments, as the blue light having a relatively short wavelength in a visible ray area is incident to each of the first quantum dot QD1 and the second quantum dot QD2, an absorption coefficient of the first quantum dot QD1 and the second quantum dot QD2 may be increased. Accordingly, finally, efficiency of light emitted from the first sub-pixel SPX1 and the second sub-pixel SPX2 may be improved and suitable color reproducibility may be secured. In addition, because the light-emitting unit EMU of the first to third sub-pixels SPX1, SPX2, and SPX3 is configured by using the light-emitting elements LD of a same color (for example, the blue light-emitting element), manufacturing efficiency of the display device DD may be increased.

The scattering layer LSL may be provided to efficiently use the light of the third color (or blue) emitted from the light-emitting element LD. For example, when the light-emitting element LD is the blue light-emitting element for emitting the blue light and when the third sub-pixel SPX3 is a blue pixel, the scattering layer LSL may include at least one type of scattering body SCT to efficiently use the light emitted from the light-emitting element LD. For example, the scattering body SCT of the scattering layer LSL may include various light scattering particles or light scattering materials. For example, the scattering body may include one or more of a group of silica (SiOx) (for example, silica bead, hollow silica, and the like), titanium oxide (TiOx), zirconium oxide (ZrOx), aluminum oxide (AlxOy), indium oxide (InxOy), zinc oxide (ZnOx), tin oxide (SnOx), and/or antimony oxide (SbxOy). However, the disclosure is not limited thereto. Meanwhile, the scattering body SCT may be located outside the third sub-pixel SPX3, and may be selectively included in the first color conversion layer CCL1 or the second color conversion layer CCL2. According to one or more embodiments, the scattering body SCT may be omitted, and thus the scattering layer LSL including a transparent polymer may be provided.

A first capping layer CPL1 may be located on the color conversion layer CCL. The first capping layer CPL1 may be provided over the first to third sub-pixels SPX1, SPX2, and SPX3. The first capping layer CPL1 may cover the color conversion layer CCL. The first capping layer CPL1 may reduce or prevent damage or contamination of the color conversion layer CCL due to permeation of an impurity, such as moisture or air from the outside.

The first capping layer CPL1 may be an inorganic layer, and may include one or more of a group of silicon nitride (SiNx), aluminum nitride (AlNx), titanium nitride (TiNx), silicon oxide (SiOx), aluminum oxide (AlxOy), titanium oxide (TiOx), silicon oxycarbide (SiOxCy), and/or silicon oxynitride (SiOxNy).

An optical layer OPL may be located on the first capping layer CPL1. The optical layer OPL may serve to improve light extraction efficiency by recycling light provided from the color conversion layer CCL by total reflection. To this end, the optical layer OPL may have a relatively low refractive index compared to the color conversion layer CCL.

A second capping layer CPL2 may be located on the optical layer OPL. The second capping layer CPL2 may be provided over the first to third sub-pixels SPX1, SPX2 and SPX3. The second capping layer CPL2 may cover the optical layer OPL. The second capping layer CPL2 may reduce or prevent damage or contamination of the optical layer OPL due to permeation of an impurity, such as moisture or air from the outside.

The second capping layer CPL2 may be an inorganic layer, and may include one or more of a group of silicon nitride (SiNx), aluminum nitride (AlNx), titanium nitride (TiNx), silicon oxide (SiOx), aluminum oxide (AlxOy), titanium oxide (TiOx), silicon oxycarbide (SiOxCy), and/or silicon oxynitride (SiOxNy).

A planarization layer PLL may be located on the second capping layer CPL2. The planarization layer PLL may be provided over the first to third sub-pixels SPX1, SPX2, and SPX3.

The planarization layer PLL may include an organic material, such as acrylic resin, epoxy resin, phenol resin, polyamide resin, polyimide resin, polyester resin, polyphenylenesulfide resin, or benzocyclobutene. However, the disclosure is not necessarily limited thereto, and the planarization layer PLL may include various types of inorganic materials, such as silicon oxide (SiOx), silicon nitride (SiNx), silicon oxynitride (SiOxNy), aluminum nitride (AlNx), aluminum oxide (AlxOy), zirconium oxide (ZrOx)), hafnium oxide (HfOx), or titanium oxide (TiOx).

A color filter layer CFL may be located on the planarization layer PLL. The color filter layer CFL may include color filters CF1, CF2, and CF3 corresponding to the color of each pixel PXL. Because the color filters CF1, CF2, and CF3 corresponding to the colors of the respective first to third sub-pixels SPX1, SPX2, and SPX3 are located, a full color image may be displayed.

The color filter layer CFL may include a first color filter CF1 located in the first sub-pixel SPX1 to selectively transmit light emitted from the first sub-pixel SPX1, a second color filter CF2 located in the second sub-pixel SPX2 to selectively transmit light emitted from the second sub-pixel SPX2, and a third color filter CF3 located in the third sub-pixel SPX3 to selectively transmit light emitted from the third sub-pixel SPX3.

According to one or more embodiments, the first color filter CF1, the second color filter CF2, and the third color filter CF3 may be a red color filter, a green color filter, and a blue color filter, respectively, but are not necessarily limited thereto. Hereinafter, when referring to an arbitrary color filter among the first color filter CF1, the second color filter CF2, and the third color filter CF3, or comprehensively referring to two or more types of color filters, the arbitrary color filter or the color filters are referred to as a “color filter” or “color filters”.

The first color filter CF1 may overlap the first color conversion layer CCL1 in the thickness direction (for example, the third direction DR3) of the base layer BSL. The first color filter CF1 may include a color filter material that selectively transmits the light of the first color (or red). For example, when the first sub-pixel SPX1 is a red pixel, the first color filter CF1 may include a red color filter material.

The second color filter CF2 may overlap the second color conversion layer CCL2 in the thickness direction (for example, the third direction DR3) of the base layer BSL. The second color filter CF2 may include a color filter material that selectively transmits the light of the second color (or green). For example, when the second sub-pixel SPX2 is a green pixel, the second color filter CF2 may include a green color filter material.

The third color filter CF3 may overlap the scattering layer LSL in the thickness direction (for example, the third direction DR3) of the base layer BSL. The third color filter CF3 may include a color filter material that selectively transmits the light of the third color (or blue). For example, when the third sub-pixel SPX3 is a blue pixel, the third color filter CF3 may include a blue color filter material.

According to one or more embodiments, a light-blocking layer BM may be further located between the first to third color filters CF1, CF2, and CF3. As described above, when the light-blocking layer BM is formed between the first to third color filters CF1, CF2, and CF3, a color mixing defect viewed from a front surface or a side surface of the display device DD may be reduced or prevented. A material of the light-blocking layer BM is not particularly limited and may include various light absorbing materials. For example, the light-blocking layer BM may include a black matrix, or the first to third color filters CF1, CF2, and CF3 may be stacked on each other to implement the light-blocking layer BM.

An overcoat layer OC may be located on the color filter layer CFL. The overcoat layer OC may be provided over the first to third sub-pixels SPX1, SPX2, and SPX3. The overcoat layer OC may cover a lower member including the color filter layer CFL. The overcoat layer OC may reduce or prevent permeation of moisture or air into the above-described lower member. In addition, the overcoat layer OC may protect the above-described lower member from a foreign substance, such as dust.

The overcoat layer OC may include an organic material, such as acrylic resin, epoxy resin, phenol resin, polyamide resin, polyimide resin, polyester resin, polyphenylenesulfide resin, or benzocyclobutene. However, the disclosure is not necessarily limited thereto, and the overcoat layer OC may include various types of inorganic materials, such as silicon oxide (SiOx), silicon nitride (SiNx), silicon oxynitride (SiOxNy), aluminum nitride (AlNx), aluminum oxide (AlxOy), zirconium oxide (ZrOx), hafnium oxide (HfOx), or titanium oxide (TiOx).

An outer film layer OFL may be located on the overcoat layer OC. The outer film layer OFL may be located outside the display device DD to reduce an external influence. The outer film layer OFL may be provided over the first to third sub-pixels SPX1, SPX2, and SPX3. According to one or more embodiments, the outer film layer OFL may include one of a polyethyleneterephthalate (PET) film, a low reflection film, a polarizing film, and a transmittance controllable film, but is not necessarily limited thereto. According to one or more embodiments, the pixel PXL may include an upper substrate other than the outer film layer OFL.

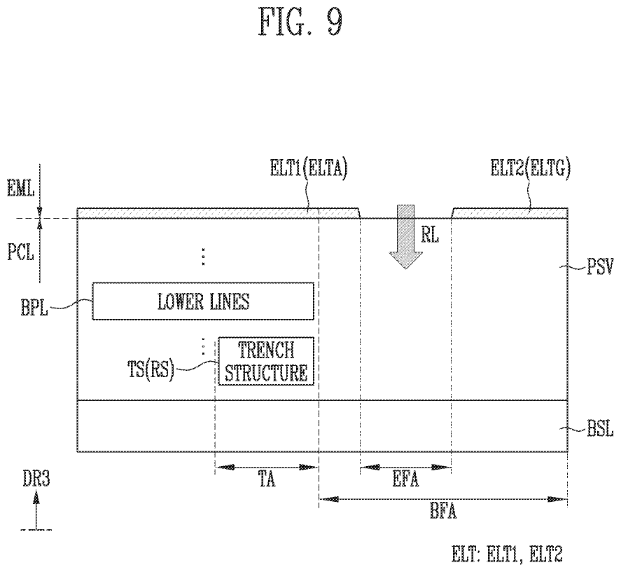

Next, a structure of the display device DD including the trench structure TS (or the reflective structure RS) is described in more detail with reference to FIGS. 9 to 18. A content that may overlap the above-described content is briefly described or is not repeated.

FIGS. 9 to 18 are schematic diagrams illustrating a structure of a display device including a trench structure according to one or more embodiments.

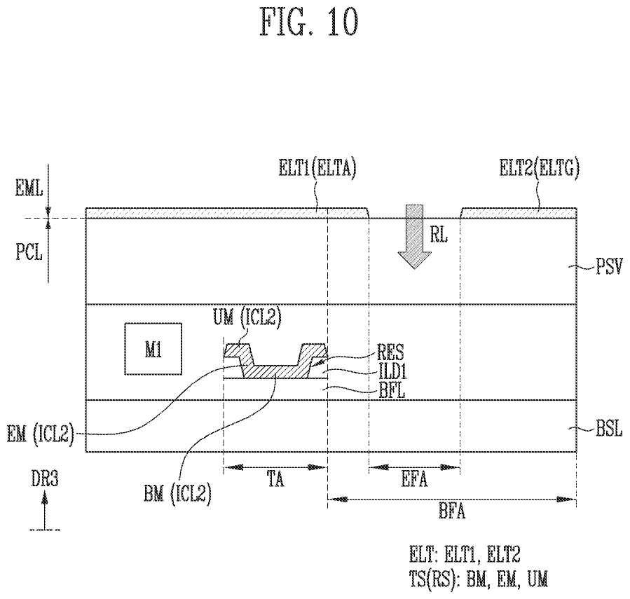

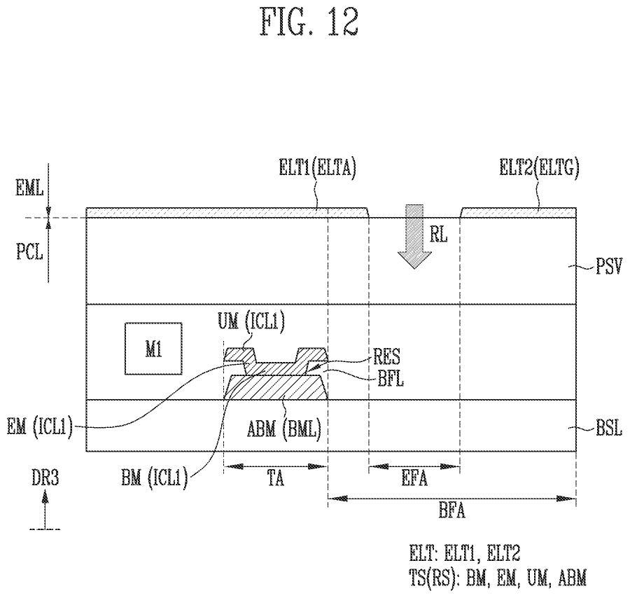

FIGS. 9 and 12 may be schematic cross-sectional views illustrating a disposition relationship of the trench structure TS for the lower lines BPL and the alignment electrode layer ELT. FIG. 9 schematically shows configurations of the pixel-circuit layer PCL and the light-emitting-element layer EML on the base layer BSL. FIGS. 10 to 12 schematically show configurations of the light-emitting-element layer EML, and shows layers of the trench structure TS according to one or more embodiments.

Referring to FIGS. 9 to 12, the lower lines BPL may be located (or patterned) in one area of the pixel-circuit layer PCL. For example, one or more of the lower auxiliary electrode layer BML, the first interlayer conductive layer ICL1, and/or the second interlayer conductive layer ICL2 may be located in one area of the pixel-circuit layer PCL.

The lower lines BPL may be selectively located only in some areas, and thus the pixel-circuit layer PCL may include a line-free area BFA in which the lower lines BPL are not located. For example, the line-free area BFA may not overlap the lower lines BPL in a plan view. In the line-free area BFA, insulating layer(s) (for example, one or more of the buffer layer BFL, the gate-insulating layer G1, the first interlayer insulating layer ILD1, the second interlayer insulating layer ILD2, and/or the protective layer PSV) may be located on the base layer BSL in the pixel-circuit layer PCL. According to one or more embodiments, an electrode or a semiconductor structure for forming the first transistor M1 may be located in an area except for the line-free area BFA.

The alignment electrode layer ELT may be located (or patterned) in one area of the light-emitting-element layer EML. The alignment electrode layer ELT may expose at least a portion of one surface of the pixel-circuit layer PCL. For example, the first alignment electrode ELTA or the second alignment electrode ELTG may be located in a partial area of the pixel-circuit layer PCL.

The first alignment electrode ELTA and the second alignment electrode ELTG may be selectively located only in a partial area to form an electrode-free area EFA. For example, the electrode-free area EFA may be an area defined by spacing the first alignment electrode ELTA and the second alignment electrode ELTG apart from each other. According to one or more embodiments, the electrode-free area EFA may be entirely covered by the line-free area BFA in a plan view. For example, the electrode-free area EFA may be entirely included in the line-free area BFA in a plan view.

The electrode-free area EFA may overlap the light-emitting elements LD in a plan view. For example, the electrode-free area EFA may correspond to an alignment area in which the light-emitting elements LD are arranged between the first alignment electrode ELTA and the second alignment electrode ELTG.

The electrode-free area EFA may not overlap the lower lines BPL in a plan view. The electrode-free area EFA may overlap the line-free area BFA in a plan view.

According to one or more embodiments, the light-emitting elements LD may be aligned based on the electric field formed between the first alignment electrode ELTA and the second alignment electrode ELTG. Experimentally, when the lower lines BPL are formed in an area between the first alignment electrode ELTA and the second alignment electrode ELTG, the formed electric fields may be interfered with by the lower lines BPL, and thus there may exist a concern that an alignment degree of the light-emitting elements LD and reliability for the alignment are compromised. However, according to one or more embodiments, because the electrode-free area EFA corresponding to an alignment area in which the light-emitting elements LD are arranged may overlap the line-free area BFA in which the lower lines BPL are not formed, the above-described risk may be substantially reduced or prevented. For example, an influence of the electrical signals (for example, the electric field and the like) for aligning the light-emitting elements LD may be reduced, and finally, the alignment degree of the light-emitting elements LD may be substantially improved.

The pixel-circuit layer PCL may include the trench structure TS located on the base layer BSL. The trench structure TS may be a conductive structure having a trench shape. According to one or more embodiments, the trench structure TS may have a well structure. An area where the trench structure TS is located may be defined as a trench area TA.

For example, a portion of the trench structure TS may have a structure recessed in the thickness direction of the base layer BSL. According to one or more embodiments, the trench structure TS may include an upper member UM, a lower member BM, and an extension member EM formed in a same process and including a same material. The upper member UM may be located at a relatively high position with respect to the base layer BSL. The lower member BM may be located at a relatively low position with respect to the base layer BSL. The lower member BM may be located between the upper member UM and the base layer BSL. The extension member EM may connect the upper member UM and the lower member BM. Because the extension member EM connects the upper member UM and the lower member BM, which are respectively located at different heights, the extension member EM may form a reflective surface RES facing areas spaced apart in a horizontal direction.

According to one or more embodiments, the trench structure TS may be formed by at least a portion of the lower lines BPL.

For example (FIG. 10), the trench structure TS may be formed by any one layer of the lower lines BPL. For example, the trench structure TS may be formed by the second interlayer conductive layer ICL2. The lower member BM of the trench structure TS may be located on the buffer layer BFL, the upper member UM may be located on the first interlayer insulating layer ILD1, and the extension member EM may be located on a side surface facing an opening formed by the first interlayer insulating layer ILD1.

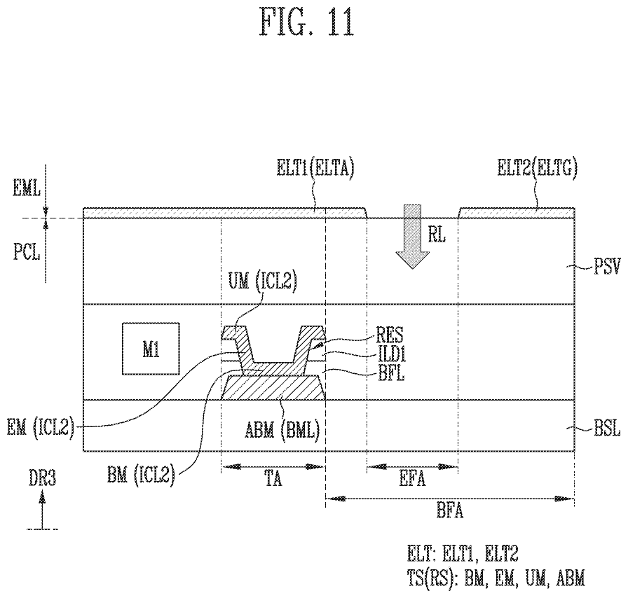

In another example (FIGS. 11 and 12), the trench structure TS may be formed by two or more layers of the lower lines BPL. The trench structure TS may further include an additional lower member ABM connected to the lower member BM. The additional lower member ABM may be a layer that is more adjacent to the base layer BSL than the lower member BM, and may be connected to the lower member BM. For example, the trench structure TS may be formed by the auxiliary lower electrode layer BML and the second interlayer conductive layer ICL2. The additional lower member ABM of the trench structure TS may be formed by the lower auxiliary electrode layer BML, and the lower member BM, the extension member EM, and the upper member UM may be formed by the second interlayer conductive layer ICL2. Alternatively, the trench structure TS may be formed by the lower auxiliary electrode layer BML and the first interlayer conductive layer ICL1. The additional lower member ABM of the trench structure TS may be formed by the lower auxiliary electrode layer BML, and the lower member BM, the extension member EM, and the upper member UM may be formed by the first interlayer conductive layer ICL1.

According to one or more embodiments, the lowermost portion of the trench structure TS may contact the base layer BSL. For example, the lower member BM may contact the base layer BSL. In another example, the additional lower member ABM may contact the base layer BSL. However, the disclosure is not limited thereto.

The trench structure TS may be located between at least a portion of the pixel circuit PXC and the electrode-free area EFA in a plan view. For example, the trench structure TS may be located between the first transistor M1 and the electrode-free area EFA in a plan view. The trench structure TS may be located between the first transistor M1 and the light-emitting element LD in a plan view.

According to one or more embodiments, some of the light emitted by the light-emitting element LD may be provided as rear surface light RL. For example, the rear surface light RL may be applied to a lower portion through the electrode-free area EFA.

At this time, the trench structure TS may be located between the first transistor M1 and the electrode-free area EFA in a plan view, and thus the likelihood that the rear surface light RL being applied to at least a portion of the pixel circuit PXC may be reduced or prevented. For example, because the trench structure TS may be located between the first transistor M1 and the electrode-free area EFA in a plan view, a risk that the rear surface light RL is applied to at least a portion (for example, the first active layer ACT1) of the first transistor M1 may be reduced or prevented. In addition, the rear surface light RL may be diffused to another area through an interface between insulating layers located in the pixel-circuit layer PCL (for example, layers selected from the buffer layer BFL, the gate-insulating layer G1, the first interlayer insulating layer ILD1, and the second interlayer insulating layer ILD2). For example, the rear surface light RL may be diffused to another area through an interface between the buffer layer BFL and the first interlayer insulating layer ILD1. However, the trench structure TS may be located from a lower area to an upper area by passing through one or more of the insulating layers (that is, the lower member BM and the extension member EM may be defined), and thus at least a portion of light diffused at the interface between the insulating layers may be blocked or reduced.

The trench structure TS may reflect at least a portion of the rear surface light RL to reduce or prevent the likelihood of the rear surface light RL being applied to a circuit element. For example, the trench structure TS may include (or form) the reflective surface RES. For example, the extension member EM may include (or form) the reflective surface RES.

The reflective surface RES may extend in a direction that is different from a direction in which a plane corresponding to one surface of the base layer BSL extends. For example, the base layer BSL may be located on a plane defined by the first direction DR1 and the second direction DR2.

At this time, the reflective surface RES may extend in a direction that is different from the direction in which the defined plane extends. The reflective surface RES may be non-parallel to the direction in which the defined plane extends. According to one or more embodiments, the reflective surface RES may form a surface extending in a direction between the direction in which the defined plane extends and the third direction DR3. According to one or more embodiments, the reflective surface RES may include a tapered surface extending in a direction that is different from the direction in which the defined plane extends.

The reflective surface RES may face the light-emitting element LD in a plan view. The reflective surface RES may face the electrode-free area EFA in a plan view. According to one or more embodiments, the reflective surface RES may face the line-free area BFA in a plan view.

Accordingly, the trench structure TS may be located adjacent to the circuit element to provide a structure for controlling a light path. Furthermore, because a disposition relationship of the trench structure TS is determined based on the electrode-free area EFA and the first transistor M1, a risk that light is applied to the element forming the pixel circuit PXC may be reduced or prevented. Experimentally, when light is applied to the element forming the pixel circuit PXC, reliability of an electrical signal may be damaged, such as a shift of a threshold-voltage of the transistors M1, M2, and M3, but the disclosure may reduce such a risk.

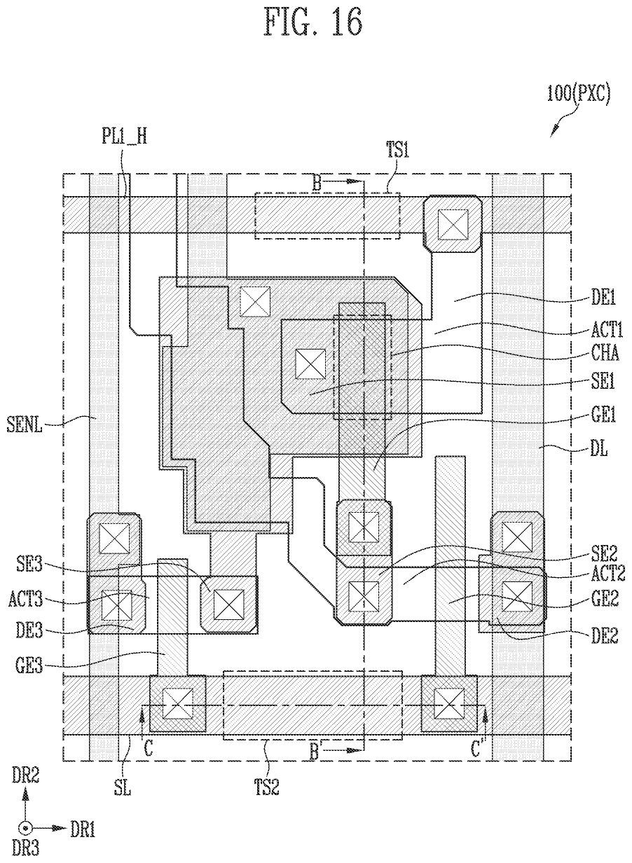

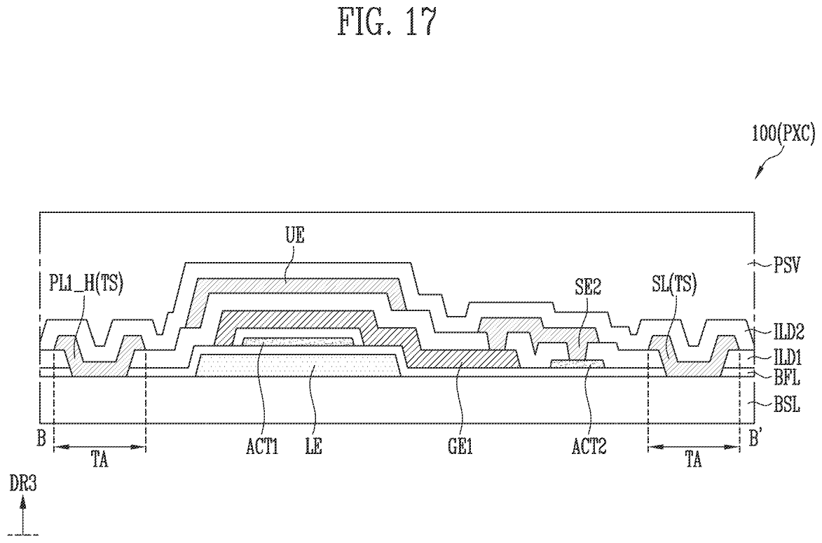

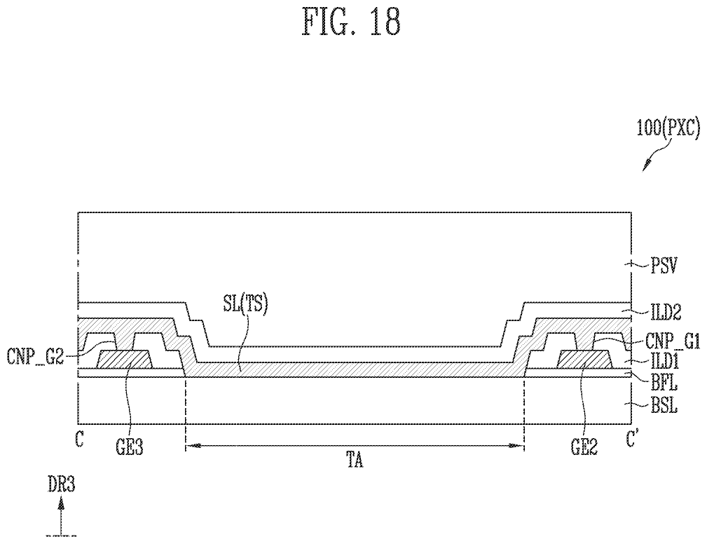

FIGS. 13 to 18 show a positional relationship between the lower lines BPL and the trench structure TS in more detail. FIGS. 13 to 15 are schematic plan views illustrating a display device according to one or more embodiments. FIG. 16 is a schematic enlarged view of a partial area 100 of FIG. 13. FIG. 17 is a schematic cross-sectional view taken along the line B-B′ of FIG. 16. FIG. 18 is a schematic cross-sectional view taken along the line C-C′ of FIG. 16.

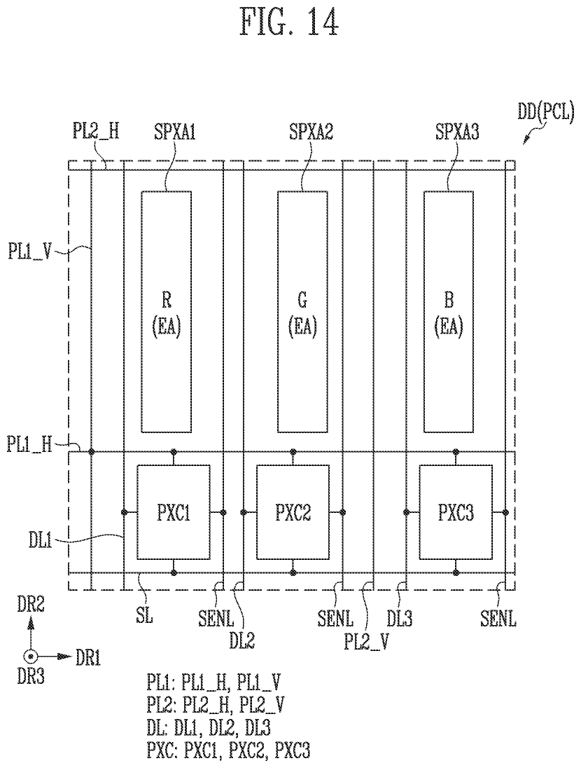

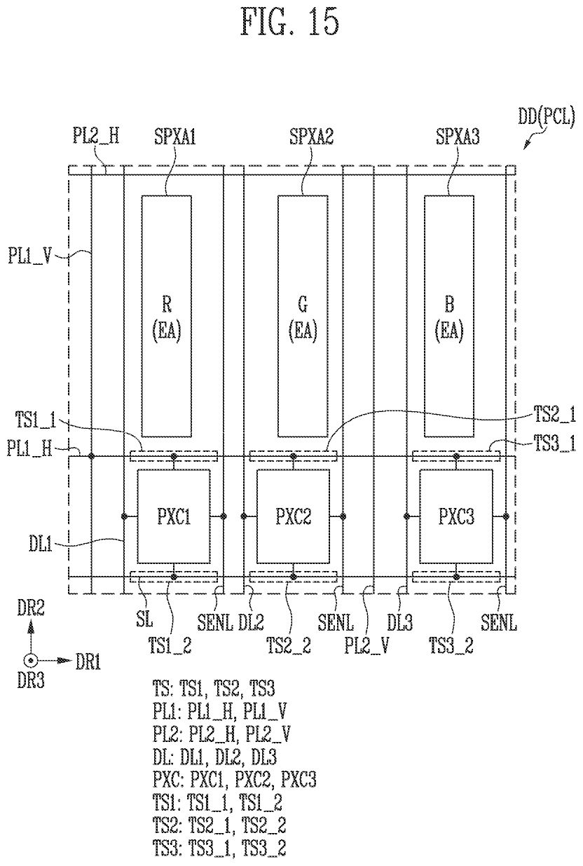

FIGS. 13 to 15 are schematic plan views illustrating an electrode structure according to one or more embodiments. FIGS. 13 to 15 may be views mainly showing a structure of the lower lines BPL. FIG. 13 may be a schematic view illustrating a planar structure of electrodes based on the electrode patterns described above with reference to FIG. 5. FIGS. 14 and 15 are plan views illustrating an area corresponding to FIG. 13, and may be plan views schematically illustrated to intuitively describe an electrode structure according to one or more embodiments.

FIG. 13 shows the lower auxiliary electrode layer BML, the active layer ACT, the first interlayer conductive layer ICL1, and the second interlayer conductive layer ICL2. In FIG. 13, the lower auxiliary electrode layer BML, the first interlayer conductive layer ICL1, and the second interlayer conductive layer ICL2 are shown in a same pattern as the pattern shown in FIG. 5, and the active layer ACT is shown as an outline without a pattern so that layers may be clearly distinguished. The above-described first contact portion CNP1 and second contact portion CNP2 are expressed by a quadrangle marked with a relatively thick line.

In FIG. 13, the contact members CNP for electrically connecting different patterns (for example, the lower auxiliary electrode layer BML, the active layer ACT, the first interlayer conductive layer ICL1, and the second interlayer conductive layer ICL2) are shown to have a shape marked with an X in a quadrangular shape. In addition, in FIG. 13, one or more embodiments in which the scan line SL and the scan control line SSL are integrated is shown.

Referring to FIGS. 13 to 18, the lower lines BPL for forming the pixel-circuit layer PCL may be located (or patterned) in one area, and the pixel circuits PXC and lines connected to the pixel circuits PXC may be formed.

The pixel circuit PXC may include a first pixel circuit PXC1, a second pixel circuit PXC2, and a third pixel circuit PXC3. Each of the first pixel circuit PXC1, the second pixel circuit PXC2, and the third pixel circuit PXC3 may include the first transistor M1, the second transistor M2, the third transistor M3, and the storage capacitor CST. The first pixel circuit PXC1, the second pixel circuit PXC2, and the third pixel circuit PXC3 may be spaced apart from each other on the second direction DR2. Each of the first pixel circuit PXC1, the second pixel circuit PXC2, and the third pixel circuit PXC3 may be the pixel circuit PXC for the respective sub-pixels SPX. For example, the first pixel circuit PXC1 may correspond to the first sub-pixel SPX1, the second pixel circuit PXC2 may correspond to the second sub-pixel SPX2, and the third pixel circuit PXC3 may correspond to the third sub-pixel SPX3.

According to one or more embodiments, the first transistor M1 of each of the first pixel circuit PXC1, the second pixel circuit PXC2, and the third pixel circuit PXC3 may include a first source electrode SE1, a first gate electrode GE1, a first drain electrode DE1, and a first active layer ACT1. According to one or more embodiments, the second transistor M2 of each of the first pixel circuit PXC1, the second pixel circuit PXC2, and the third pixel circuit PXC3 may include a second source electrode SE2, a second gate electrode GE2, a second drain electrode DE2, and a second active layer ACT2. According to one or more embodiments, the third transistor M3 of each of the first pixel circuit PXC1, the second pixel circuit PXC2, and the third pixel circuit PXC3 may include a third source electrode SE3, a third gate electrode GE3, a third drain electrode DE3, and a third active layer ACT3.

The storage capacitor CST may include an upper electrode UE and a lower electrode LE. According to one or more embodiments, the storage capacitor CST may include a first storage capacitor CST1 included in the first pixel circuit PXC1, a second storage capacitor CST2 included in the second pixel circuit PXC2, and a third storage capacitor CST3 included in the third pixel circuit PXC3. According to one or more embodiments, each of the upper electrode UE and the lower electrode LE may include one or more selected from among the lower auxiliary electrode layer BML, the first interlayer conductive layer ICL1, and the second interlayer conductive layer ICL2.

The scan line SL may extend in the first direction DR1. The scan line SL may be formed by the second interlayer conductive layer ICL2. According to one or more embodiments, the scan line SL and the scan control line SSL may be integrally formed.

The data lines DL may extend in the second direction DR2. The data lines DL may be spaced apart from each other in the first direction DR1. The data lines DL may include a first data line DL1, a second data line DL2, and a third data line DL3. The first data line DL1 may be a data line for the first pixel circuit PXC1 and may be electrically connected to the second drain electrode DE2 of the second transistor M2 of the first pixel circuit PXC1. The second data line DL2 may be a data line for the second pixel circuit PXC2 and may be electrically connected to the second drain electrode DE2 of the second transistor M2 of the second pixel circuit PXC2. The third data line DL3 may be a data line for the third pixel circuit PXC3 and may be electrically connected to the second drain electrode DE2 of the second transistor M2 of the third pixel circuit PXC3.

The sensing line SENL may extend in the second direction DR2. The sensing line SENL may be electrically connected to the third drain electrode DE3 of the third transistor M3 of the first to third pixel circuits PXC1, PXC2, and PXC3. The sensing line SENL may be formed by the lower auxiliary electrode layer BML.

The first power line PL1 may include a (1_1)-th power line PL1_H extending in the first direction DR1 and a (1_2)-th power line PL1_V extending in the second direction DR2. The (1_1)-th power line PL1_H and the (1_2)-th power line PL1_V may be electrically connected through one contact member CNP. Accordingly, the first power line PL1 may be formed in a mesh structure, and may be electrically connected to the first drain electrode DE1 of the first transistor M1 of the first to third pixel circuits PXC1, PXC2, and PXC3.

The second power line PL2 may include a (2_1)-th power line PL2_H extending in the first direction DR1 and a (2_2)-th power line PL2_V extending in the second direction DR2. The (2_1)-th power line PL2_H and the (2_2)-th power line PL2_V may be electrically connected through one contact member CNP. Accordingly, the second power line PL2 may be formed in a mesh structure, and may be electrically connected to the second electrode ELT2 (for example, the second alignment electrode ELTG) (or the second connection electrode CNE2).

The emission area EA may be formed so as not to overlap the lower lines BPL. For example, the light-emitting elements LD may be located so as not to overlap the lower lines BPL.

The emission area EA may be formed so as not to overlap the lower lines BPL. For example, the light-emitting elements LD may be located so as not to overlap the lower lines BPL.

The emission area EA may include a first emission area R, a second emission area G, and a third emission area B. The first emission area R may be an area where the light-emitting elements LD for forming the first sub-pixel SPX1 are located. The first emission area R may overlap the first sub-pixel area SPXA1 in a plan view. The second emission area G may be an area where the light-emitting elements LD for forming the second sub-pixel SPX2 are located. The second emission area G may overlap the second sub-pixel area SPXA2 in a plan view. The third emission area B may be an area where the light-emitting elements LD for forming the third sub-pixel SPX3 are located. The third emission area B may overlap the third sub-pixel area SPXA3 in a plan view.

The emission area EA may not overlap the lower lines BPL in a plan view. The first emission area R, the second emission area G, and the third emission area B may be located in an area where the lower lines BPL are not located. According to one or more embodiments, the first emission area R may be located between the first data line DL1 and the sensing line SENL for the first pixel circuit PXC1. The second emission area G may be located between the second data line DL2 and the sensing line SENL for the second pixel circuit PXC2. The third emission area B may be located between the third data line DL3 and the sensing line SENL for the third pixel circuit PXC3.

FIGS. 13 to 15 illustrate a structure in which the emission area EA is located above the pixel circuits PXC. According to one or more embodiments, the emission area EA may also be located below the pixel circuits PXC. Accordingly, the emission areas EA located below the pixel circuits PXC may form a pixel PXL that is different from that of the emission areas EA located above the pixel circuits PXC.

The trench structure TS may extend in a direction (for example, in the first direction DR1) that is different from a direction in which the emission area EA and the pixel circuit PXC are spaced apart from each other.

According to one or more embodiments, the trench structure TS may include trench structures TS1, TS2, and TS3 spaced apart from each other. For example, the trench structure TS may include a first trench structure TS1, a second trench structure TS2, and a third trench structure TS3. According to one or more embodiments, the first trench structure TS1, the second trench structure TS2, and the third trench structure TS3 may be sequentially located along a direction (for example, the first direction DR1) in which the first to third pixel circuits PXC1, PXC2, and PXC3 are sequentially located.

The trench structure TS may be located between the pixel circuit PXC and the emission area EA. For example, the trench structure TS may be located between the first transistor M1 and the emission area EA. The first trench structure TS1 may be located between the first transistor M1 of the first pixel circuit PXC1 and the first emission area R. The second trench structure TS2 may be located between the first transistor M1 of the second pixel circuit PXC2 and the second emission area G. The third trench structure TS3 may be located between the first transistor M1 of the third pixel circuit PXC3 and the third emission area B.

The trench structure TS may overlap, or may be aligned with, the emission area EA and the pixel circuit PXC in the second direction DR2 in a plan view. For example, the first trench structure TS1 may overlap, or may be aligned with, the first emission area R and the first pixel circuit PXC1 in the second direction DR2 in a plan view. The second trench structure TS2 may overlap, or may be aligned with, the second emission area G and the second pixel circuit PXC2 in the second direction DR2 in a plan view. The third trench structure TS3 may overlap, or may be aligned with, the third emission area B and the third pixel circuit PXC3 in the second direction DR2 in a plan view.

The trench structure TS might not overlap, or might not be aligned with, the emission area EA and the pixel circuit PXC in the first direction DR1 in a plan view. For example, the first trench structure TS1 might not overlap, or might not be aligned with, the first emission area R and the first pixel circuit PXC1 in the first direction DR1. The second trench structure TS2 might not overlap, or might not be aligned with, the second emission area G and the second pixel circuit PXC2 in the first direction DR1. The third trench structure TS3 might not overlap, or might not be aligned with, the third emission area B and the third pixel circuit PXC3 in the first direction DR1.

According to the above-described disposition structure of the trench structure TS, the trench structure TS may effectively block the rear surface light RL applied from the emission area EA.

According to one or more embodiments, the trench structure TS may include structures in which two or more trench structures are sequentially located in one trench area TA. In this case, because two or more trench structures overlap along a direction in which the rear surface light RL is applied, a light-blocking effect may be greater.

According to one or more embodiments, the trench structure TS may include a portion located on one side of a corresponding pixel circuit PXC, and another portion located on another side of the corresponding pixel circuit PXC. In this case, in a structure in which the emission area EMA is formed on one side and another side of the pixel circuit PXC, the trench structure TS may effectively block a path through which light is applied to the pixel circuit PXC.

For example, the first trench structure TS1 may include a (1-1)-th trench structure TS1-1 located on one side of the first pixel circuit PXC1 and a (1-2)-th trench structure TS1-2 located on another side of the first pixel circuit PXC1. The second trench structure TS2 may include a (2-1)-th trench structure TS2-1 located on one side of the second pixel circuit PXC2 and a (2-2)-th trench structure located on another side of the second pixel circuit PXC2. The third trench structure TS3 may include a (3-1)-th trench structure TS3-1 located on one side of the third pixel circuit PXC3 and a (3-2)-th trench structure TS3-2 located on another side of the third pixel circuit PXC3.

According to one or more embodiments, the (1-1)-th trench structure TS1-1, the (2-1)-th trench structure TS2-1, and the (3-1)-th trench structure TS3-1 may be first side trench structures located adjacent to a first side of the pixel circuit PXC. The (1-2)-th trench structure TS1-2, the (2-2)-th trench structure TS2-2, and the (3-2)-th trench structure TS3-2 may be second side trench structures located adjacent to a second side of the pixel circuit PXC. The second side may be opposite to the first side.

According to one or more embodiments, the trench structure TS may be formed integrally with one or more of lines electrically connected to the pixel circuit PXC. For example, an electrical signal supplied to the line electrically connected to the pixel circuit PXC may be applied to the trench structure TS.

For example, the (1-1)-th trench structure TS1-1, the (2-1)-th trench structure TS2-1, and the (3-1)-th trench structure TS3-1 may be formed integrally with the (1_1)-th power line PL1_H. According to one or more embodiments, the (1-1)-th trench structure TS1-1, the (2-1)-th trench structure TS2-1, the (3-1)-th trench structure TS3-1, and the (1_1)-th power line PL1_H may be formed by the second interlayer conductive layer ICL2, and a same electrical signal may be applied to the (1-1)-th trench structure TS1-1, the (2-1)-th trench structure TS2-1, the (3-1)-th trench structure TS3-1, and the (1_1)-th power line PL1_H. In addition, according to one or more embodiments, the (1-2)-th trench structure TS1-2, the (2-2)-th trench structure TS2-2, and the (3-2)-th trench structure TS3-2 may be formed integrally with the scan line SL. According to one or more embodiments, the (1-2)-th trench structure TS1-2, the (2-2)-th trench structure TS2-2, the (3-2)-th trench structure TS3-2, and the scan line SL may be formed by the second interlayer conductive layer ICL2, and a same electrical signal may be applied to the (1-2)-th trench structure TS1-2, the (2-2)-th trench structure TS2-2, the (3-2)-th trench structure TS3-2, and the scan line SL. However, the disclosure is not necessarily limited thereto.

According to one or more embodiments, the trench structure TS may overlap (e.g., may be aligned with) at least a portion of the first transistor M1 in the second direction DR2. For example, the (1-1)-th trench structure TS1-1 may overlap, or may be aligned with, the first active layer ACT1 (for example, a channel area CHA of the first active layer ACT1) in the second direction DR2. The (1-2)-th trench structure TS1-2 may overlap the first active layer ACT1 on the second direction DR2. The first active layer ACT1 may be entirely included in the trench area TA where the trench structure TS is located, based on the second direction DR2.

According to one or more embodiments, the trench structure TS may overlap a portion of each of the second transistor M2 and the third transistor M3 in the second direction DR2. For example, the (1-1)-th trench structure TS1-1 may overlap at least a portion of each of the second active layer ACT2 and the third active layer ACT3 in the second direction DR2. The (1-2)-th trench structure TS1-2 may overlap at least a portion of each of the second active layer ACT2 and the third active layer ACT3 in the second direction DR2.

According to one or more embodiments, the trench structure TS may be located between the contact portions CNP formed in the pixel-circuit layer PCL. For example, the scan line SL may be electrically connected to the second gate electrode GE2 through a first gate contact portion CNP_G1. The scan line SL may be electrically connected through the third gate electrode GE3 through a second gate contact portion CNP_G2. At this time, the trench structure TS may be located between the first gate contact portion CNP_G1 and the second gate contact portion CNP_G2. However, the disclosure is not necessarily limited thereto. According to one or more embodiments, the trench structure TS may be formed to at least partially overlap the contact portion CNP. For example, because a same electrical signal may be applied to the scan line SL and the trench structure TS, the trench structure TS may be formed to overlap the first gate contact portion CNP_G1 and the second gate contact portion CNP_G2.

As described above, although the disclosure has been described with reference to the preferred embodiment above, those skilled in the art or those having a common knowledge in the art will understand that the disclosure may be variously modified and changed without departing from the spirit and technical area of the disclosure described in the claims which will be described later.

Therefore, the technical scope of the disclosure should not be limited to the contents described in the detailed description of the specification, but should be defined by the claims, with functional equivalents thereof to be included therein.

What is claimed is:

1. A display device comprising:
a base layer;
a pixel-circuit layer above the base layer, and comprising:
a pixel circuit comprising a transistor comprising an active layer; and
a trench structure adjacent to the active layer and having reflexibility; and
a light-emitting element above the pixel-circuit layer.

2. The display device according to claim 1, wherein the base layer is above a plane defined by a first direction, and by a second direction that is different from the first direction, and
wherein the trench structure comprises a reflective surface extending in a direction that is different from a direction in which the plane extends.

3. The display device according to claim 2, wherein the trench structure comprises a lower member, an upper member, and an extension member connecting the lower member and the upper member,
wherein the upper member is spaced further from the base layer than the lower member, and
wherein one surface of the extension member defines the reflective surface.

4. The display device according to claim 3, wherein the pixel-circuit layer comprises lower lines comprising the pixel circuit, a lower auxiliary electrode layer above the base layer, a first interlayer conductive layer above the lower auxiliary electrode layer, and a second interlayer conductive layer above the first interlayer conductive layer and comprising the trench structure.

5. The display device according to claim 3, wherein the pixel-circuit layer comprises lower lines comprising the pixel circuit, the trench structure, a lower auxiliary electrode layer above the base layer and comprising an additional lower member of the trench structure between the lower member and the base layer, a first interlayer conductive layer above the lower auxiliary electrode layer, and a second interlayer conductive layer above the first interlayer conductive layer, and
wherein the first interlayer conductive layer or the second interlayer conductive layer comprises the lower member, the extension member, and the upper member.

6. The display device according to claim 1, further comprising:
a first electrode and a second electrode above the pixel-circuit layer;
a line-free area in which lower lines, which are of the pixel-circuit layer, and which form the pixel circuit and the trench structure, are not located; and
an electrode-free area defined by the first electrode and the second electrode being spaced apart from each other, and
wherein the electrode-free area is entirely in the line-free area in a plan view.

7. The display device according to claim 6, wherein the electrode-free area overlaps the light-emitting element in plan view.

8. The display device according to claim 6, wherein the transistor comprises a driving transistor, and
wherein the trench structure is between at least a portion of the driving transistor and the electrode-free area in plan view.

9. The display device according to claim 8, wherein the active layer comprises a driving active layer of the driving transistor, and
wherein the trench structure is between the active layer and the light-emitting element in plan view.

10. The display device according to claim 1, wherein the trench structure comprises a first trench structure, a second trench structure, and a third trench structure, and
wherein the pixel circuit comprises a first pixel circuit, a second pixel circuit, and a third pixel circuit sequentially arranged in a first direction and below the first trench structure, the second trench structure, and the third trench structure in a second direction crossing the first direction in plan view.

11. The display device according to claim 10, further comprising an emission area in which the light-emitting element is located, and comprising a first emission area, a second emission area, and a third emission area above the first pixel circuit, the second pixel circuit, and the third pixel circuit in the second direction,
wherein the first trench structure is aligned with the first pixel circuit and the first emission area in the second direction,
wherein the second trench structure is aligned with the second pixel circuit and the second emission area in the second direction, and
wherein the third trench structure is aligned with the third pixel circuit and the third emission area in the second direction.

12. The display device according to claim 10, wherein the trench structure has a shape extending on the first direction.

13. The display device according to claim 1, wherein the pixel-circuit layer comprises a line electrically connected to the pixel circuit and integrally formed with the trench structure.

14. The display device according to claim 13, wherein the transistor comprises a first transistor comprising a first gate electrode, a second transistor comprising a second gate electrode, and a third transistor comprising a third gate electrode,
wherein the line comprises a scan line electrically connected to the second gate electrode through a first gate contact portion, and electrically connected to the third gate electrode through a second gate contact portion, and
wherein the trench structure is between the first gate contact portion and the second gate contact portion in plan view.

15. The display device according to claim 13, wherein the transistor comprises a switching transistor, and
wherein the line comprises a scan line electrically connected to a gate electrode of the switching transistor, and integrally formed with the trench structure.

16. The display device according to claim 13, wherein the line comprises a first power line integrally formed with the trench structure for supplying first power, and a second power line for supplying second power.

17. The display device according to claim 13, wherein the trench structure comprises a first side trench structure adjacent a first side of the pixel circuit in plan view, and a second side trench structure adjacent a second side of the pixel circuit that is opposite to the first side in plan view.

18. The display device according to claim 17, wherein the transistor comprises a switching transistor, and
wherein the line comprises a scan line electrically connected to a gate electrode of the switching transistor and integrally formed with the second side trench structure, a first power line integrally formed with the first side trench structure for supplying first power, and a second power line for supplying second power.

19. A display device comprising:
a base layer on a plane defined by a first direction, and by a second direction that is different from the first direction;
a pixel-circuit layer above the base layer, and comprising a pixel circuit comprising a transistor; and
a light-emitting element above the pixel-circuit layer,
wherein the pixel circuit comprises a reflective structure that is between the transistor and the light-emitting element in a plan view and that comprises a reflective surface that is non-parallel to a direction in which the plane extends.

20. A display device comprising:
a base layer;
a pixel-circuit layer comprising lower lines above the base layer; and
a light-emitting-element layer above the pixel-circuit layer, and comprising a first electrode, a second electrode, and a light-emitting element between the first electrode and the second electrode;
a line-free area in which the lower lines are not located; and
an electrode-free area defined by the first electrode and the second electrode being spaced apart from each other, and entirely within the line-free area in a plan view,
wherein a portion of the lower lines comprises a pixel circuit comprising a transistor, and at least another portion of the lower lines comprises a reflective structure, the reflective structure comprising a reflective surface between the transistor and the electrode-free area and facing the electrode-free area.
